(19) United States
(12) Patent Application Publication
(10) Pub. No.: US 2026/0032923 A1
(43) Pub. Date: Jan. 29, 2026

(54) SEMICONDUCTOR DEVICE AND METHOD FOR FABRICATING THE SAME

(71) Applicant: SK hynix Inc., Gyeonggi-do (KR)

(72) Inventors: Gil Seop KIM, Gyeonggi-do (KR); Jung Won SEO, Gyeonggi-do (KR)

(21) Appl. No.: 19/017,794

(22) Filed: Jan. 13, 2025

(30) Foreign Application Priority Data
Jul. 29, 2024 (KR) 10-2024-0100266

(51) Int. Cl. H10B 80/00; H01L 23/00; H01L 25/00; H01L 25/065; H01L 25/18; H10B 12/00

(52) U.S. Cl. CPC H10B 80/00; H01L 24/08; H01L 24/80; H01L 25/0657; H01L 25/18; H01L 25/50; H10B 12/03; H10B 12/05; H10B 12/30; H01L 2224/08145; H01L 2224/80006; H01L 2224/80895; H01L 2224/80896; H01L 2924/1431; H01L 2924/1436

(57) ABSTRACT

A semiconductor device including high-integrated memory cells and a method for fabricating the semiconductor device is provided. The method may include forming a first bonding dielectric layer on a substrate, sequentially forming a mold stack, a blocking layer, and a second bonding dielectric layer on a sacrificial substrate to create a stack structure, flipping the stack structure including the sacrificial substrate, bonding the first bonding dielectric layer and the second bonding dielectric layer, removing the sacrificial substrate from the stack structure, and forming a plurality of memory cells vertically stacked in the mold stack of the stack structure, using the blocking layer as a barrier.

### CROSS-REFERENCE TO RELATED APPLICATIONS

The present application claims priority under 35 U.S.C 119 (a) to Korean Patent Application No. 10-2024-0100266, filed on Jul. 29, 2024, which is incorporated herein by reference in its entirety.

### BACKGROUND

### 1. Field

Various embodiments of the present disclosure relate to a semiconductor device, and more particularly, to a semiconductor device including three-dimensional (3D) memory cells, and a method for fabricating the semiconductor device.

### 2. Description of the Related Art

Recently, in order to cope with the large capacity and miniaturization of a memory device, a three-dimensional (3D) memory device in which a plurality of memory cells are stacked has been proposed.

### SUMMARY

Embodiments of the present disclosure are directed to a semiconductor device including high-integrated memory cells, and a method for fabricating the semiconductor device.

In accordance with an embodiment of the present disclosure, a method for fabricating a semiconductor device may include forming a first bonding dielectric layer on a substrate; sequentially forming a mold stack, a blocking layer, and a second bonding dielectric layer on a sacrificial substrate to create a stack structure; flipping the stack structure including the sacrificial substrate; bonding the first bonding dielectric layer and the second bonding dielectric layer; removing the sacrificial substrate from the stack structure; and forming a plurality of memory cells vertically stacked in the mold stack of the stack structure, using the blocking layer as a barrier.

In accordance with an embodiment of the present disclosure, a semiconductor device may include a substrate; a bonding dielectric layer formed on the substrate; a blocking layer formed on the bonding dielectric layer; and a memory cell array formed over the blocking layer, the memory cell array including a plurality of memory cells vertically stacked over the blocking layer.

In accordance with an embodiment of the present disclosure, a semiconductor device may include a first conductive line vertically oriented in a first direction; a vertical stack including second conductive lines that intersect the first conductive line and are horizontally oriented in a second direction; and a blocking layer disposed above the vertical stack and the first conductive line.

In accordance with an embodiment of the present disclosure, a semiconductor device may include a memory cell array including a plurality of memory cells vertically stacked; a peripheral circuit portion suitable for controlling the memory cells of the memory cell array; a bonding structure between the memory cell array and the peripheral circuit portion; and a blocking layer spaced apart from the bonding structure and covering a portion of the memory cell array.

In accordance with an embodiment of the present disclosure, a method for fabricating a semiconductor device may include forming a first bonding dielectric layer on a first substrate; sequentially forming a mold stack, a blocking layer, and a second bonding dielectric layer on a sacrificial substrate to create a first structure; flipping the first structure including the sacrificial substrate; bonding the first bonding dielectric layer and the second bonding dielectric layer; removing the sacrificial substrate from the stack structure; forming a memory cell array including a plurality of memory cells vertically stacked in the mold stack, using the blocking layer as a barrier, to create a second structure; forming a peripheral circuit portion over a second substrate; flipping the second structure; bonding the memory cell array and the peripheral circuit portion; and removing the first substrate and the second bonding dielectric layer.

### BRIEF DESCRIPTION OF THE DRAWINGS

FIG. 1A is a schematic perspective view illustrating a memory cell in accordance with an embodiment of the present disclosure.

FIG. 1B is a schematic cross-sectional view illustrating the memory cell illustrated in FIG. 1A.

FIG. 2A is a schematic view illustrating a semiconductor device in accordance with an embodiment of the present disclosure.

FIG. 2B is a schematic perspective view illustrating a memory cell array illustrated in FIG. 2A.

FIG. 2C is an equivalent circuit view illustrating a column array illustrated in FIG. 2B.

FIG. 2D is an equivalent circuit view illustrating a row array illustrated in FIG. 2B.

FIG. 3 is a schematic plan view illustrating a semiconductor device in accordance with an embodiment of the present disclosure.

FIG. 4A is a cross-sectional view illustrating the semiconductor device taken along line A-A′ illustrated in FIG. 3.

FIG. 4B is a cross-sectional view illustrating the semiconductor device taken along line B-B′ illustrated in FIG. 3.

FIGS. 5 to 7 illustrate various views of a mold stack structure formed utilizing a method for fabricating the mold stack structure in accordance with an embodiment of the present disclosure.

FIGS. 8A to 26B illustrate various views of a structure formed utilizing a method for fabricating a memory cell array in accordance with an embodiment of the present disclosure.

FIGS. 27A to 27E are various views illustrating a memory cell array and a bonding processor of a peripheral circuit portion in accordance with an embodiment of the present disclosure.

FIG. 28 is a schematic cross-sectional view illustrating a semiconductor device in accordance with an embodiment of the present disclosure.

FIGS. 29A and 29B are various views illustrating a stack assembly in accordance with an embodiment of the present disclosure.

FIGS. 30 and 31 illustrate various views of a mold stack structure formed utilizing a method for fabricating the mold stack structure in accordance with an embodiment of the present disclosure.

FIG. 32 is a schematic view illustrating a semiconductor device in accordance with an embodiment of the present disclosure.

### DETAILED DESCRIPTION

Various embodiments of the present disclosure described herein may be described with reference to cross-sectional views, plan views and block diagrams, which are ideal schematic views of a semiconductor device. It is noted that the structures of the drawings may be modified by fabricating techniques and/or tolerances. The embodiments of the present disclosure are not limited to the described embodiments and the specific structures illustrated in the drawings, but may include other embodiments, or modifications of the described embodiments including any changes in the structures that may be produced according to requirements of the fabricating process. Accordingly, the regions illustrated in the drawings have schematic attributes, and the shapes of the regions illustrated in the drawings are intended to illustrate specific structures of regions of the elements, and are not intended to limit the scope of the disclosure.

The following embodiment relates to three-dimensional memory cells, in which memory cells are vertically stacked to increase memory cell density and reduce parasitic capacitance.

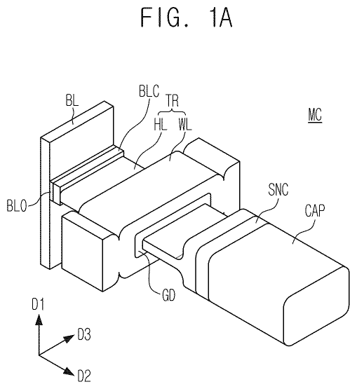

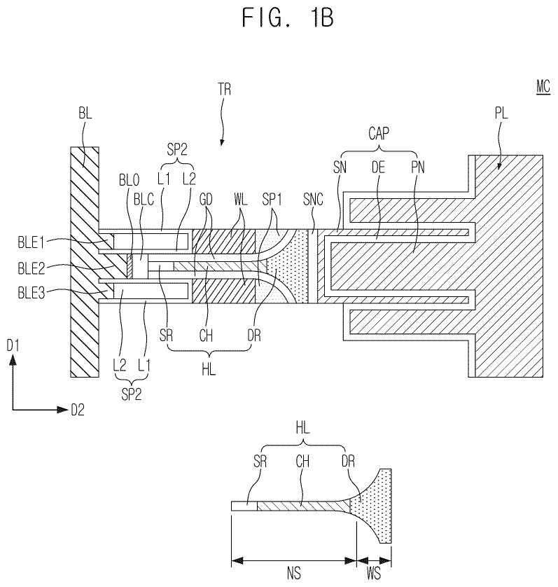

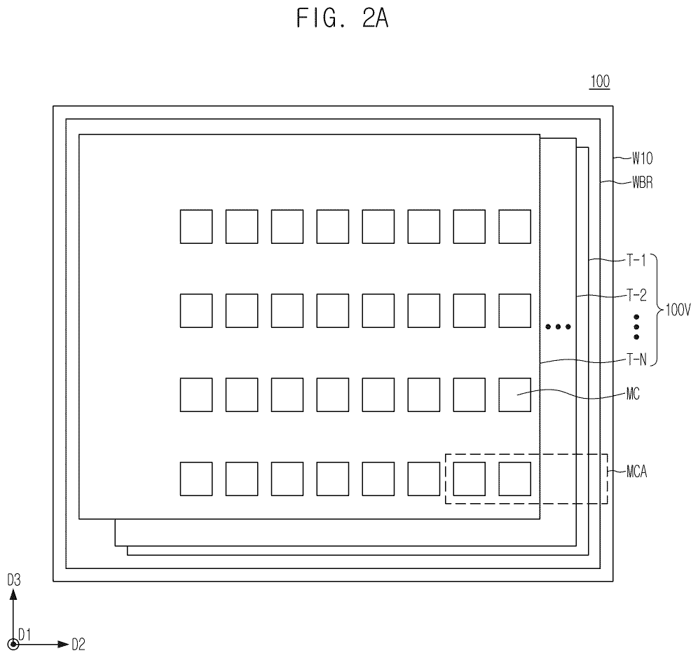

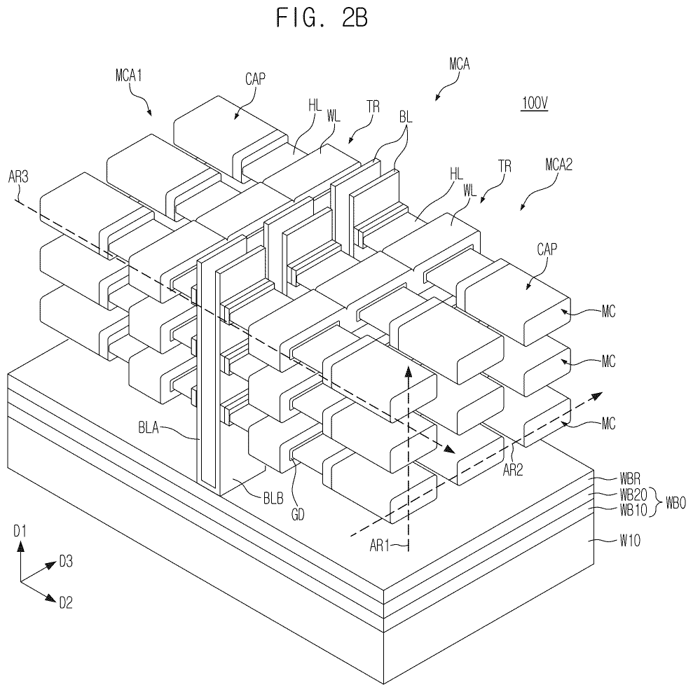

FIG. 1A is a schematic perspective view illustrating a memory cell MC in accordance with an embodiment of the present disclosure. FIG. 1B is a schematic cross-sectional view illustrating the memory cell MC illustrated in FIG. 1A.

Referring to FIGS. 1A and 1B, the memory cell MC may include a first conductive line BL, a switching element TR, and a data storage element CAP.

The first conductive line BL may be vertically oriented in a first direction D1. The first conductive line BL may include a bit line. The first conductive line BL may be referred to as a “vertical conductive line”, a “vertically-oriented bit line”, a “vertically-extending bit line”, or a “pillar-shaped bit line”. The first conductive line BL may include a conductive material. The first conductive line BL may include a silicon-based material, a metal-based material, or a combination thereof. The first conductive line BL may include polysilicon, metal, metal nitride, metal silicide, or a combination thereof. The first conductive line BL may include polysilicon, titanium nitride, tungsten, or a combination thereof. For example, the first conductive line BL may include a titanium nitride/tungsten (TiN/W) stack in which titanium nitride and tungsten are sequentially stacked.

The switching element TR has a function of controlling voltage or current supply to the data storage element CAP during a data write operation and a data read operation performed onto the data storage element CAP. The switching element TR may include a nano sheet HL, a nano sheet dielectric layer GD, and a second conductive line WL. The second conductive line WL may include a horizontal conductive line or a horizontal word line, and the nano sheet HL may include an active layer. The switching element TR may include a transistor, and in this case, the second conductive line WL may serve as a gate electrode. The switching element TR may also be referred to as a “nano sheet transistor”, an “access element” or a “selection element”. The second conductive line WL may be referred to as a “horizontal gate electrode” or a “horizontal word line”.

The nano sheet HL may extend in a second direction D2 that intersects with the first direction D1, i.e., is perpendicular to the first direction D1. The second conductive line WL may extend in a third direction D3 that intersects with the first direction D1 and the second direction D2. The first direction D1 may be a vertical direction, and the second direction D2 may be a first horizontal direction, and the third direction D3 may be a second horizontal direction. The nano sheet HL may extend in the first horizontal direction, i.e., the second direction D2. The second conductive line WL may extend in the second horizontal direction, i.e., the third direction D3. The nano sheet HL may be referred to as a “horizontal layer”.

The nano sheet HL may include a channel CH, a first doped region SR between the channel CH and the first conductive line BL, and a second doped region DR between the channel CH and the data storage element CAP. The first doped region SR may be electrically coupled to the first conductive line BL, and the second doped region DR may be electrically coupled to the data storage element CAP. A height of the second doped region DR in the first direction D1 may be greater than heights of the first doped region SR and the channel CH in the first direction D1. A length of the second doped region DR in the second direction D2 may be less than a length of the channel CH in the second direction D2. Lengths of the first doped region SR, the channel CH and the second doped region DR in the third direction D3 may be equal to one another.

The nano sheet HL may include a first region NS and a second region WS that are horizontally disposed in the second direction D2. The second region WS may extend from the first region NS. The second region WS may have a thickness that gradually increases in the second direction D2 from the first region NS toward the data storage element CAP between the first region NS and the data storage element CAP. An average vertical height or thickness of the second region WS in the first direction D1 may be greater than that of the first region NS. Hereinafter, the first region NS is referred to as a “narrow sheet”, and the second region WS is referred to as a “wide sheet”.

The narrow sheet NS may have a flat plate shape. The wide sheet WS may have a fan-like shape. The wide sheet WS may have a thickness that gradually increases in the second direction D2. The narrow sheet NS may be referred to as a “flat plate-shaped sheet”, and the wide sheet WS may be referred to as a “fan-like shaped sheet”. A boundary portion between the narrow sheet NS and the wide sheet WS may have a curvature.

The first doped region SR and the channel CH may be disposed in the narrow sheet NS, and the second doped region DR may be disposed in the wide sheet WS. The channel CH formed in the narrow sheet NS may be referred to as a “narrow channel” or a “flat channel”. A portion of the second doped region DR may extend to be disposed in the narrow sheet NS. The second doped region DR may include a thick portion disposed in the wide sheet WS and a thin portion disposed in the narrow sheet NS. One side of the wide sheet WS contacting the data storage element CAP and one side of the second doped region DR may each have a flat side shape.

A horizontal length of the wide sheet WS in the second direction D2 may be less than that of the narrow sheet NS. The narrow sheet NS may be referred to as a “long sheet”, and the wide sheet WS may be referred to as a “short sheet”.

The nano sheet HL may include a semiconductor material. For example, the nano sheet HL may include polysilicon, monocrystalline silicon, germanium, or silicon-germanium. In some embodiments, the nano sheet HL may include an oxide semiconductor material. For example, the oxide semiconductor material may include indium gallium zinc oxide (IGZO), InSnZnO, ZnSnO, or a combination thereof. In some embodiments, the nano sheet HL may include conductive metal oxide. In some embodiments, the nano sheet HL may include a two-dimensional material, for example, MoS₂, WS₂, or MoSe₂.

When the nano sheet HL is formed of the oxide semiconductor material, the channel CH may also be formed of the oxide semiconductor material, and the first and second doped regions SR and DR may be omitted. The nano sheet HL may also be referred to as an “active layer” or a “thin body”.

The first doped region SR and the second doped region DR may be doped with the same conductivity type of impurities. Each of the first doped region SR and the second doped region DR may be doped with an N-type conductive impurity or a P-type conductive impurity. The first doped region SR and the second doped region DR may include at least one impurity selected from among arsenic (As), phosphorus (P), boron (B), indium (In), and combinations thereof. The first doped region SR may be electrically coupled to the first conductive line BL, and the second doped region DR may be electrically coupled to the data storage element CAP. The first and second doped regions SR and DR may be referred to as “first and second source/drain regions”.

The nano sheet HL may be horizontally oriented in the second direction D2 from the first conductive line BL.

The second conductive line WL may have a gate all around structure (GAA). For example, the second conductive line WL may surround the nano sheet HL and extend in the third direction D3. The nano sheet dielectric layer GD may be formed between the nano sheet HL and the second conductive line WL. The nano sheet dielectric layer GD may surround the nano sheet HL. The second conductive line WL may surround the nano sheet HL on the nano sheet dielectric layer GD.

The second conductive line WL may include a metal-based material, a semiconductor material, or a combination thereof. The second conductive line WL may include molybdenum, molybdenum nitride, ruthenium, titanium nitride, tungsten, polysilicon, or a combination thereof. For example, the second conductive line WL may include a TiN/W stack in which titanium nitride and tungsten are sequentially stacked. The second conductive line WL may include an N-type work function material or a P-type work function material. The N-type work function material may have a low work function of approximately 4.5 eV or less, and the P-type work function material may have a high work function of approximately 4.5 eV or greater. The second conductive line WL may include a stack of a low work function material and a high work function material.

The nano sheet dielectric layer GD may be disposed between the nano sheet HL and the second conductive line WL. The nano sheet dielectric layer GD may be referred to as a “gate dielectric layer” or a “channel-side dielectric layer”. The nano sheet dielectric layer GD may include silicon oxide, silicon nitride, metal oxide, metal oxide nitride, metal silicate, a high-k material, a ferroelectric material, an anti-ferroelectric material, or a combination thereof. The nano sheet dielectric layer GD may include SiO₂, Si₃N₄, HfO₂, Al₂O₃, ZrO₂, AlON, HfON, HfSiO, HfSiON, HfZrO, or a combination thereof. The nano sheet dielectric layer GD may be formed by a thermal oxidation process of a semiconductor material.

The data storage element CAP may include a memory element such as a capacitor. The data storage element CAP may be horizontally disposed in the second direction D2 from the switching element TR. The data storage element CAP may include a first electrode SN, a second electrode PN on the first electrode SN, and a dielectric layer DE between the first electrode SN and the second electrode PN. The first electrode SN may horizontally extend in the second direction D2 from the nano sheet HL. The first electrode SN, the dielectric layer DE and the second electrode PN may be horizontally disposed in the second direction D2. The first electrode SN may include an inner space and a plurality of outer surfaces. The inner space of the first electrode SN may include a plurality of inner surfaces. The outer surfaces of the first electrode SN may include a vertical outer surface and a plurality of horizontal outer surfaces. The vertical outer surface of the first electrode SN may vertically extend in the first direction D1. The horizontal outer surfaces of the first electrode SN may horizontally extend in the second direction D2 or the third direction D3. The inner space of the first electrode SN may be a three-dimensional space. The dielectric layer DE may conformally cover the inner surfaces of the first electrode SN. The second electrode PN may be disposed in the inner space of the first electrode SN on the dielectric layer DE. Some of the outer surfaces of the first electrode SN may be electrically coupled to the second doped region DR of the nano sheet HL. The second electrode PN of the data storage element CAP may be coupled to a common plate PL.

The data storage element CAP may have a three-dimensional structure. The first electrode SN may have a three-dimensional structure, which may have a horizontal three-dimensional structure that is oriented in the second direction D2. In an example of the three-dimensional structure, the first electrode SN may have a cylindrical shape. The cylindrical shape of the first electrode SN may include cylindrical inner surfaces and cylindrical outer surfaces. Some of the cylindrical outer surfaces of the first electrode SN may be electrically coupled to the second doped region DR of the nano sheet HL. The dielectric layer DE and the second electrode PN may be disposed on the cylindrical inner surfaces of the first electrode SN.

In some embodiments, the first electrode SN may have a pillar shape or a pylinder shape. The pylinder shape may refer to a structure in which a pillar shape and a cylindrical shape are merged.

The first electrode SN and the second electrode PN may include metal, noble metal, metal nitride, conductive metal oxide, conductive noble metal oxide, metal carbide, metal silicide, or a combination thereof. For example, the first electrode SN and the second electrode PN may include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, or a combination thereof. The second electrode PN may also include a combination of a metal-based material and a silicon-based material. For example, the second electrode PN may be a titanium nitride/silicon germanium/tungsten nitride (TiN/SiGe/WN) stack. In the titanium nitride/silicon germanium/tungsten nitride (TiN/SiGe/WN) stack, silicon germanium may be a gap-fill material that fills the inside of the first electrode SN, titanium nitride (TiN) may serve as the second electrode PN of the data storage element CAP, and tungsten nitride may be a low-resistance material.

The dielectric layer DE may be referred to as a “capacitor dielectric layer” or a “memory layer”. The dielectric layer DE may include silicon oxide, silicon nitride, a high-k material, a perovskite material, or a combination thereof. The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). In some embodiments, the dielectric layer DE may be formed of a composite layer including two or more layers of the above-described high-k material.

The dielectric layer DE may be formed of zirconium (Zr)-based oxide. The dielectric layer DE may have a stack structure containing zirconium oxide (ZrO₂). The dielectric layer DE may include a ZA (ZrO₂/Al₂O₃) stack or a ZAZ (ZrO₂/Al₂O₃/ZrO₂) stack. The ZA stack may have a structure in which aluminum oxide (Al₂O₃) is stacked on zirconium oxide (ZrO₂). The ZAZ stack may have a structure in which zirconium oxide (ZrO₂), aluminum oxide (Al₂O₃) and zirconium oxide (ZrO₂) are sequentially stacked. Each of the ZA stack and the ZAZ stack may be referred to as a “zirconium oxide (ZrO₂)-based layer. In some embodiments, the dielectric layer DE may be formed of hafnium (Hf)-based oxide. The dielectric layer DE may have a stack structure containing hafnium oxide (HfO₂). The dielectric layer DE may include an HA (HfO₂/Al₂O₃) stack or an HAH (HfO₂/Al₂O₃/HfO₂) stack. The HA stack may have a structure in which aluminum oxide (Al₂O₃) is stacked on hafnium oxide (HfO₂). The HAH stack may have a structure in which hafnium oxide (HfO₂), aluminum oxide (Al₂O₃) and hafnium oxide (HfO₂) are sequentially stacked. Each of the HA stack and the HAH stack may be referred to as a “hafnium oxide (HfO₂)-based layer”. In the ZA stack, ZAZ stack, HA stack and HAH stack, aluminum oxide (Al₂O₃) may have a greater band gap energy than zirconium oxide (ZrO₂) and hafnium oxide (HfO₂). Aluminum oxide (Al₂O₃) may have a lower dielectric constant than zirconium oxide (ZrO₂) and hafnium oxide (HfO₂). Accordingly, the dielectric layer DE may include a stack of a high-k material and a high band gap material having a greater band gap energy than the high-k material. The dielectric layer DE may include silicon oxide (SiO₂) as a high band gap material other than aluminum oxide (Al₂O₃). Since the dielectric layer DE includes a high band gap material, leakage current may be suppressed. The high band gap material may be thinner than the high-k material. In some embodiments, the dielectric layer DE may include a stack structure in which a high-k material and a high band gap material are alternately stacked. For example, the dielectric layer DE may include a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HAHA (HfO₂/Al₂O₃/HfO₂/Al₂O₃) stack, a HAHAH (HfO₂/Al₂O₃/HfO₂/Al₂O₃/HfO₂) stack a HZAZH (HfO₂/ZrO₂/Al₂O₃/ZrO₂/HfO₂) stack, a ZHZAZHZ (ZrO₂/HfO₂/ZrO₂/Al₂O₃/ZrO₂/HfO₂/ZrO₂) stack, a HZHZ (HfO₂/ZrO₂/HfO₂/ZrO₂) stack, or AHZAZHA (Al₂O₃/HfO₂/ZrO₂/Al₂O₃/ZrO₂/HfO₂/Al₂O₃) stack. In the above-described stack structures, aluminum oxide (Al₂O₃) may be thinner than zirconium oxide (ZrO₂) and hafnium oxide (HfO₂).

In some embodiments, the dielectric layer DE may include a high-k material and a high band gap material, and the dielectric layer DE may have a laminated structure or an intermixed structure. According to the laminated structure, a plurality of high-k materials and a plurality of high band gap materials are stacked. According to the intermixed structure, a high-k material and a high band gap material are intermixed.

In some embodiments, the dielectric layer DE may include a ferroelectric material, an anti-ferroelectric material, or a combination thereof. For example, the dielectric layer DE may include HfZrO.

In some embodiments, the dielectric layer DE may include a combination of a high-k material and a ferroelectric material, a combination of a high-k material and an anti-ferroelectric material, or a combination of a high-k material or a ferroelectric material and an anti-ferroelectric material.

In some embodiments, an interface control layer may be further formed between the first electrode SN and the dielectric layer DE to improve leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode PN and the dielectric layer DE.

The data storage element CAP may include a three-dimensional capacitor. The data storage element CAP may include a Metal-Insulator-Metal (MIM) capacitor. The data storage element CAP may be replaced with another data storage material. For example, the data storage material may be a thyristor, a phase-change material, a Magnetic Tunnel Junction (MTJ), or a variable resistance material.

The memory cell MC may further include a first contact node BLC and a second contact node SNC. The first contact node BLC may be disposed between the first conductive line BL and the nano sheet HL. The first contact node BLC may include a metal-based material or a semiconductor material. For example, the first contact node BLC may include titanium, titanium nitride, tungsten, or a combination thereof. In addition, the first contact node BLC may include doped polysilicon, and the first doped region SR may include an impurity diffused from the first contact node BLC. The second contact node SNC may be disposed between the nano sheet HL and the first electrode SN. The second contact node SNC may include a metal-based material or a semiconductor material. For example, the second contact node SNC may include titanium, titanium nitride, tungsten, or a combination thereof. In addition, the second contact node SNC may include doped polysilicon, and the second doped region DR may include an impurity diffused from the second contact node SNC. A height of the first contact node BLC in the first direction D1 may be less than a height of the second contact node SNC in the first direction D1. The height of the first contact node BLC in the first direction D1 may be greater than the height of the channel CH in the first direction D1.

In some embodiments, the second contact node SNC may be selectively grown from the wide sheet WS of the nano sheet HL. The second contact node SNC may be formed by selective epitaxial growth (SEG). For example, the second contact node SNC may be a silicon epitaxial layer formed by selective epitaxial growth (SEG). The second contact node SNC may be a doped silicon epitaxial layer.

In some embodiments, the first contact node BLC may also be selectively grown from the narrow sheet NS of the nano sheet HL. The first contact node BLC may be formed by selective epitaxial growth (SEG). For example, the first contact node BLC may be a silicon epitaxial layer formed by selective epitaxial growth (SEG). The first contact node BLC may be a doped silicon epitaxial layer.

The first contact node BLC may be a narrow sheet-side contact node, and the second contact node SNC may be a wide sheet-side contact node.

The nano sheet HL may include a first edge and a second edge. The first edge may refer to a portion of the first doped region SR electrically coupled to the first conductive line BL. The second edge may refer to a portion of the second doped region DR electrically coupled to the first electrode SN of the data storage element CAP.

The memory cell MC may further include an ohmic contact layer BLO between the first contact node BLC and the first conductive line BL. The ohmic contact layer BLO may include metal silicide. In some embodiments, the memory cell MC may further include an ohmic contact layer formed between the second contact node SNC and the first electrode SN of the data storage element CAP. The first conductive line BL, the ohmic contact layer BLO, the first contact node BLC and the first doped region SR may be electrically coupled. The second doped region DR, the second contact node SNC and the first electrode SN of the data storage element CAP may be electrically coupled.

The memory cell MC may further include a first spacer SP1 and a second spacer SP2. The first spacer SP1 may be disposed between the second conductive line WL and the second doped region DR. The second spacer SP2 may be disposed between the first conductive line BL and the second conductive line WL. The second spacer SP2 may include a stack of a first liner L1 and a second liner L2. The first and second spacers SP1 and SP2 may each include a dielectric material. The first and second spacers SP1 and SP2 may each include silicon oxide, silicon nitride, or a combination thereof. The first spacer SP1 may include silicon nitride. The first liner L1 of the second spacer SP2 may be silicon nitride, and the second liner L2 of the second spacer SP2 may be silicon oxide. The second liner L2 may partially fill an inner space of the first liner L1.

The first conductive line BL may include a plurality of horizontal extension portions BLE1, BLE2, and BLE3. The horizontal extension portions BLE1, BLE2, and BLE3 may extend in the second direction D2. The horizontal extension portions may include an inner horizontal extension portion BLE2 and outer horizontal extension portions BLE1 and BLE3. The inner horizontal extension portion BLE2 of the first conductive line BL may extend to be disposed in a gap between the first liners L1 vertically adjacent to each other. Accordingly, the inner horizontal extension portion BLE2 of the first conductive line BL may be electrically coupled to the ohmic contact layer BLO.

The outer horizontal portions BLE1 and BLE3 of the first conductive line BL may extend to be disposed in one side of the second spacer SP2. Accordingly, the outer horizontal portions BLE1 and BLE3 of the first conductive line BL may contact the second liner L2 of the second spacer SP2. In some embodiments, the outer horizontal portions BLE1 and BLE3 of the first conductive line BL may be omitted.

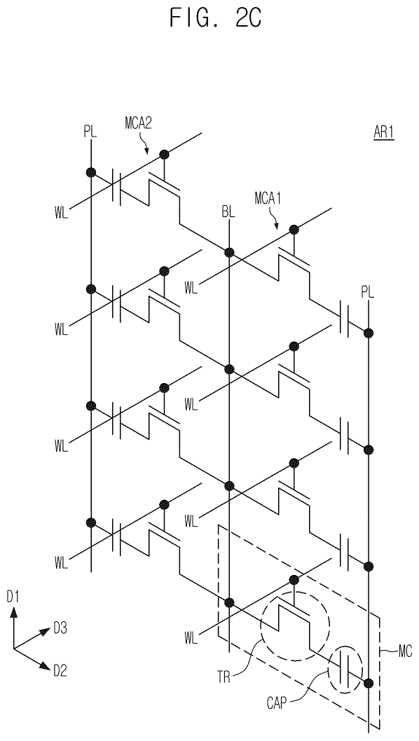

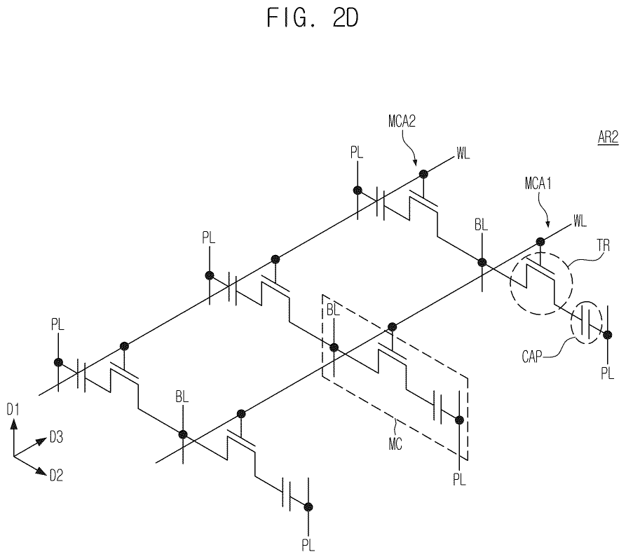

FIG. 2A is a schematic view illustrating a semiconductor device 100 in accordance with an embodiment of the present disclosure. FIG. 2B is a schematic perspective view illustrating a memory cell array MCA illustrated in FIG. 2A. FIG. 2C is an equivalent circuit view illustrating a column array AR1 illustrated in FIG. 2B. FIG. 2D is an equivalent circuit view illustrating a row array AR2 illustrated in FIG. 2B.

Referring to FIG. 2A, the semiconductor device 100 may include a substrate W10, a blocking layer WBR, and a plurality of planes T-1 to T-N. The planes T-1 to T-N may constitute a vertical stack 100V. Each of the planes T-1 to T-N may include a plurality of memory cells MC. The vertical stack 100V may include the memory cell array MCA. The memory cell array MCA may include a three-dimensional array of the memory cells MC. Detailed components of each of the memory cells MC are described above with reference to FIGS. 1A and 1B. The planes T-1 to T-N may be referred to as a “Tier”.

Referring to FIGS. 2B to 2D, the memory cell array MCA may include the plurality of memory cells MC vertically stacked in a first direction D1, the plurality of memory cells MC horizontally disposed in a second direction D2, and the plurality of memory cells MC horizontally disposed in a third direction D3.

Each of the memory cells MC may include a first conductive line BL, a switching element TR, and a data storage element CAP. The switching element TR may include a second conductive line WL, a nano sheet dielectric layer GD, and a nano sheet HL.

The memory cell array MCA may include the column array AR1 of the memory cells MC and the row array AR2 of the memory cells MC. The column array AR1 may include the plurality of memory cells MC vertically stacked in a first direction D1. The memory cells MC of the column array AR1 may share the first conductive line BL. The row array AR2 may include the plurality of memory cells MC horizontally disposed in a third direction D3. The memory cells MC of the row array AR2 may share the second conductive line WL. The first direction D1 may be a vertical direction, and the third direction D3 may be a horizontal direction. The memory cell array MCA may further include a horizontal level array AR3, which may include the plurality of memory cells MC disposed at the same horizontal level in a second direction D2. Neighboring memory cells MC of the horizontal level array AR3 may share the first conductive line BL.

The memory cell array MCA may include a first sub-cell array MCA1 and a second sub-cell array MCA2. The first sub-cell array MCA1 and the second sub-cell array MCA2 may each include a three-dimensional array of the memory cells MC. The first sub-cell array MCA1 and the second sub-cell array MCA2 may share the first conductive line BL. The first conductive line BL may include a first vertical conductive line BLA and a second vertical conductive line BLB. A bottom portion of the first vertical conductive line BLA and a bottom portion of the second vertical conductive line BLB may be merged with each other. The first conductive line BL may have a U-shape by merging the first vertical conductive line BLA and the second vertical conductive line BLB. The memory cells MC of the first sub-cell array MCA1 may share the first vertical conductive line BLA, and the memory cells MC of the second sub-cell array MCA2 may share the second vertical conductive line BLB. In this way, the neighboring first and second sub-cell arrays MCA1 and MCA2 may have a mirror-type structure of sharing the first conductive line BL. From the perspective of a top view, the first and second vertical conductive lines BLA and BLB may each have a rectangular shape.

A lower structure may be disposed below the memory cell array MCA. The lower structure may include a silicon-on-insulator (SOI) structure. For example, the lower structure may include a stack of the substrate W10, a bonding dielectric layer WBO, and the blocking layer WBR. The bonding dielectric layer WBO may have a double structure of a first bonding dielectric layer WB10 and a second bonding dielectric layer WB20. The bonding dielectric layer WBO may be formed between the substrate W10 and the blocking layer WBR. The first conductive line BL and the data storage element CAP of the memory cell array MCA may be in direct contact with the blocking layer WBR.

The substrate W10 may be a silicon-containing material, and the bonding dielectric layer WBO and the blocking layer WBR may be dielectric materials. The substrate WB10 may include a monocrystalline silicon layer. The bonding dielectric layer WBO may include silicon oxide, and the blocking layer WBR may include silicon carbon oxide (SiCO), silicon carbon nitride (SiCN), or a combination thereof. The blocking layer WBR may have a carbon content of 5 to 60 at % or more. In some embodiments, the blocking layer WBR may include a multilayer structure of a plurality of first block layers and a plurality of second blocking layers. For example, the blocking layer WBR may include an alternating stack of silicon carbon oxide layers and silicon carbon nitride layers.

A bridge between the first conductive lines BL disposed adjacent to each other in the third direction D3 may be prevented by the blocking layer WBR. In addition, a bridge between the first conductive line BL and the data storage element CAP may be prevented by the blocking layer WBR.

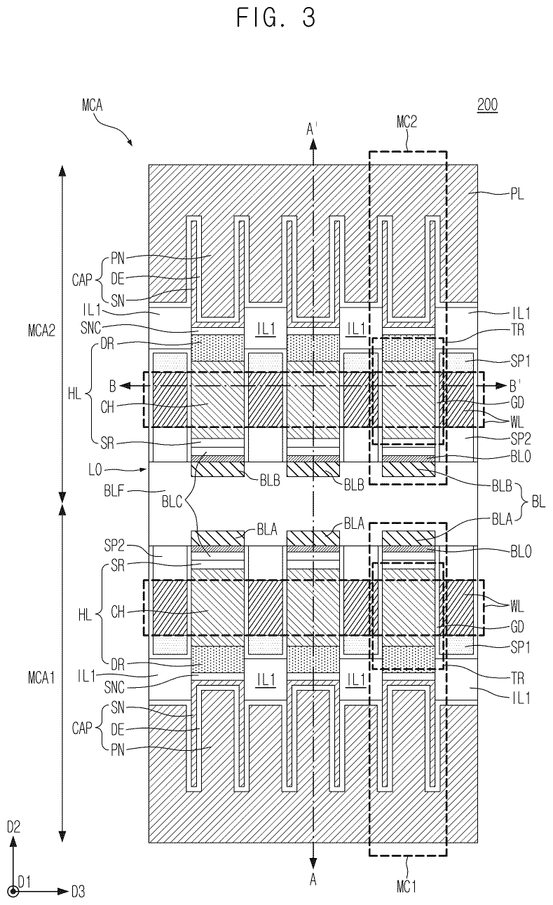

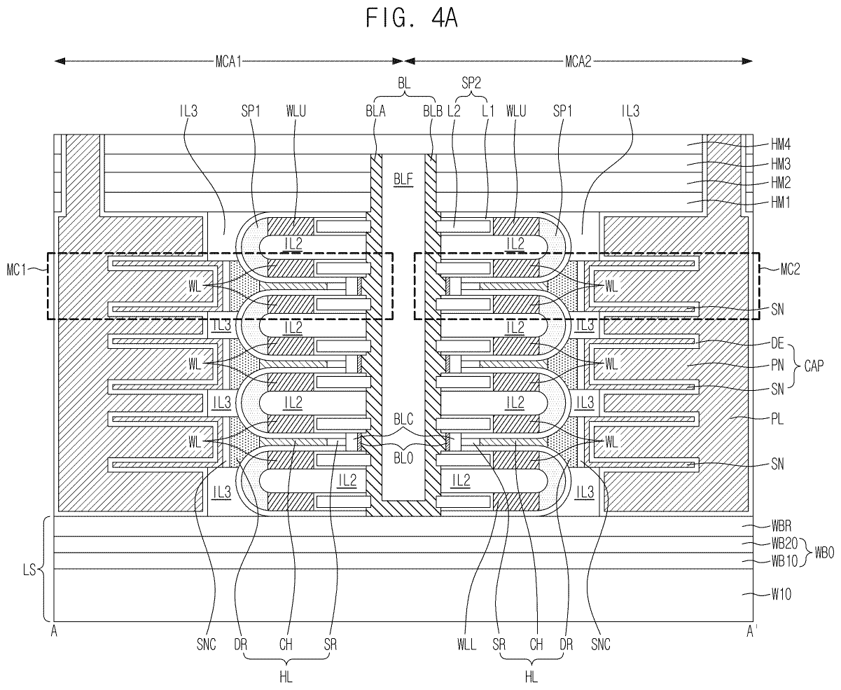

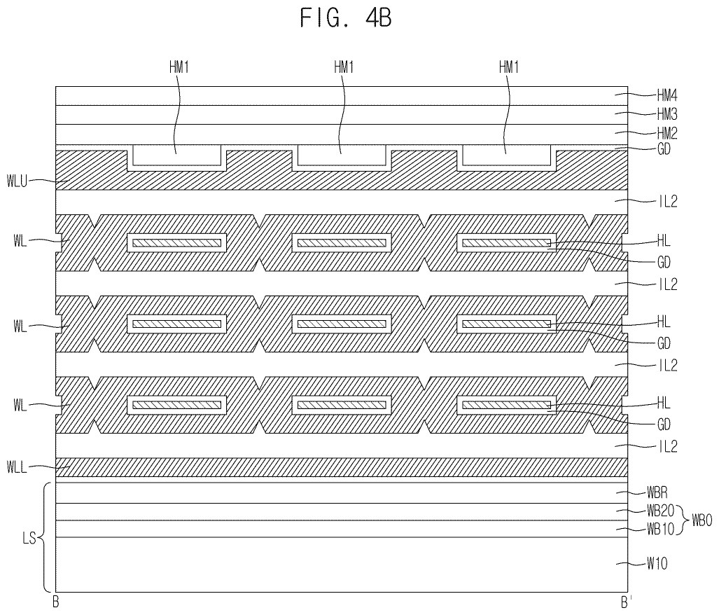

FIG. 3 is a schematic plan view illustrating a semiconductor device 200 in accordance with an embodiment of the present disclosure. FIG. 3 may be a plan view illustrating the semiconductor device 200 to describe the row array AR2 illustrated in FIG. 2B. FIG. 4A is a cross-sectional view illustrating the semiconductor device 200 taken along line A-A′ illustrated in FIG. 3. FIG. 4B is a cross-sectional view illustrating the semiconductor device 200 taken along line B-B′ illustrated in FIG. 3.

A memory cell array MCA of the semiconductor device 200 illustrated in FIGS. 3 to 4B may be similar to the memory cell array MCA illustrated in FIGS. 2A to 2D, and memory cells MC1 and MC2 of the memory cell array MCA may be similar to the memory cell MC illustrated in FIGS. 1A and 1B. Detailed descriptions of overlapping components are described above with reference to FIGS. 1A, 1B, 2A, 2B, 2C, and 2D.

Referring to FIGS. 3, 4A and 4B, the semiconductor device 200 may include the memory cell array MCA and a lower structure LS below the memory cell array MCA.

The lower structure LS may include a silicon-on-insulator (SOI) structure. For example, the lower structure LS may include a stack of a substrate W10, a bonding dielectric layer WBO, and a blocking layer WBR. The bonding dielectric layer WBO may have a double structure of a first bonding dielectric layer WB10 and a second bonding dielectric layer WB20. The bonding dielectric layer WBO may be formed between the substrate W10 and the blocking layer WBR. The substrate W10 may be a silicon-containing material, and the bonding dielectric layer WBO and the blocking layer WBR may be dielectric materials. The substrate WB10 may include a monocrystalline silicon layer. The bonding dielectric layer WBO may include silicon oxide, and the blocking layer WBR may include silicon carbon oxide (SiCO), silicon carbon nitride (SiCN) or a combination thereof. The lower structure LS may be a combination of the blocking layer WBR and the SOI structure. The SOI structure may refer to a stack of the substrate W10 and the bonding dielectric layer WBO. The SOI structure may be different from an SOI substrate. A general SOI substrate has a structure in which oxide is formed on a silicon substrate, but the SOI structure according to the present embodiment may be a structure in which the bonding dielectric layer WBO is formed on the substrate W10.

The memory cell array MCA may include a first sub-cell array MCA1 and a second sub-cell array MCA2. The first sub-cell array MCA1 may include a three-dimensional array of the memory cells MC1, and the second sub-cell array MCA2 may include a three-dimensional array of the memory cells MC2.

The memory cell array MCA may include a plurality of memory cells MC1 and MC2 vertically stacked in a first direction D1. The memory cells MC1 and MC2 may have the same configuration as the memory cell MC described with reference to FIGS. 1A and 1B. The memory cell array MCA may include the plurality of memory cells MC1 and MC2 horizontally disposed in a second direction D2. The memory cell array MCA may include the plurality of memory cells MC1 and MC2 horizontally disposed in a third direction D3. The memory cell array MCA may include a plurality of first conductive lines BL. Each of the first conductive lines BL may include a first vertical conductive line BLA and a second vertical conductive line BLB. A bottom portion of the first vertical conductive line BLA and a bottom portion of the second vertical conductive line BLB may be merged with each other.

A first memory cell MC1 of the first sub-cell array MCA1 may include the first vertical conductive line BLA, a switching element TR, and a data storage element CAP. The switching element TR of the first memory cell MC1 may include a second conductive line WL and a nano sheet HL. A second memory cell MC2 of the second sub-cell array MCA2 may include the second vertical conductive line BLB, a switching element TR, and a data storage element CAP. The switching element TR of the second memory cell MC2 may include a second conductive line WL and a nano sheet HL. The switching elements TR of the first and second memory cells MC1 and MC2 may be nano sheet transistors. The nano sheets HL of the first and second memory cells MC1 and MC2 may each include a narrow sheet NS in a flat plate shape and a wide sheet WS in a fan-like shape, as illustrated in FIG. 1B.

The first conductive line BL may vertically extend in the first direction D1. The nano sheet HL may extend in the second direction D2. The second conductive line WL may horizontally extend in the third direction D3.

A first inter-cell dielectric layer IL1 may be disposed between the data storage elements CAP disposed adjacent to each other in the third direction D3. A second inter-cell dielectric layer IL2 may be disposed between the second conductive lines WL stacked in the first direction D1. A third inter-cell dielectric layer IL3 may be disposed between first electrodes SN of the data storage elements CAP stacked in the first direction D1. The first to third inter-cell dielectric layers IL1, IL2 and IL3 may each include silicon oxide, silicon carbon oxide (SiCO), silicon nitride, or a combination thereof. The first inter-cell dielectric layer IL1 may be referred to as a “device isolation layer”.

Each of the memory cells MC1 and MC2 may further include a first contact node BLC and a second contact node SNC. The first contact node BLC may be disposed between the first conductive line (BLA and BLB) and the nano sheet HL. The first contact node BLC may include a metal-based material or a semiconductor material. For example, the first contact node BLC may include titanium, titanium nitride, tungsten, or a combination thereof. In addition, the first contact node BLC may include doped polysilicon, and a first doped region SR may include an impurity diffused from the first contact node BLC. The second contact node SNC may be disposed between the nano sheet HL and the first electrode SN. The second contact node SNC may include a metal-based material or a semiconductor material. For example, the second contact node SNC may include titanium, titanium nitride, tungsten, or a combination thereof. In addition, the second contact node SNC may include doped polysilicon, and a second doped region DR may include an impurity diffused from the second contact node SNC. A height of the first contact node BLC in the first direction D1 may be less than a height of the second contact node SNC in the first direction D1. A height of the first contact node BLC in the first direction D1 may be greater than a height of a channel CH in the first direction D1.

Each of the memory cells MC1 and MC2 may further include an ohmic contact layer BLO between the first contact node BLC and the first conductive line BL. The ohmic contact layer BLO may include metal silicide.

Each of the memory cells MC1 and MC2 may further include a first spacer SP1 and a second spacer SP2. The first spacer SP1 may be disposed between the second conductive line WL and the second doped region DR. The second spacer SP2 may be disposed between the first conductive line BL and the second conductive line WL. The second spacer SP2 may include a stack of a first liner L1 and a second liner L2. The first and second spacers SP1 and SP2 may each include a dielectric material. The first and second spacers SP1 and SP2 may each include silicon oxide, silicon nitride, or a combination thereof. The first spacer SP1 may include silicon nitride. The first liner L1 of the second spacer SP2 may be silicon nitride, and the second liner L2 of the second spacer SP2 may be silicon oxide. The first spacer SP1 may cover one side of the second inter-cell dielectric layer IL2. The first spacer SP1 may have a cup shape, for example, a “⊃” shape.

The memory cell array MCA may include a plurality of second conductive lines WL vertically stacked in the first direction D1. The memory cell array MCA may include a plurality of nano sheets HL vertically stacked in the first direction D1. The memory cell array MCA may include a plurality of data storage elements CAP vertically stacked in the first direction D1. The memory cell array MCA may include a plurality of first conductive lines BL spaced apart in the third direction D3. The memory cell array MCA may include dummy second conductive lines WLU and WLL disposed at a level higher than an uppermost-level second conductive line WL and at a level lower than a lowermost-level second conductive line WL, respectively. The dummy second conductive lines WLU and WLL may each have a linear shape extending horizontally.

The memory cell array MCA may include a stack of a plurality of hard mask layers HM1, HM2, HM3, and HM4 disposed at a level higher than the uppermost-level second conductive line WL.

A vertical isolation layer BLF may be disposed between the first vertical conductive line BLA and the second vertical conductive line BLB of the first conductive line BL. The vertical isolation layer BLF may include a dielectric material.

The nano sheets HL of the switching elements TR horizontally disposed in the third direction D3 may share one second conductive line WL. The nano sheets HL of the switching elements TR horizontally disposed in the third direction D3 may be coupled to different first conductive lines BL. The switching elements TR stacked in the first direction D1 may share one first conductive line BL. The switching elements TR horizontally disposed in the third direction D3 may share one second conductive line WL.

Second electrodes PN of the data storage elements CAP may be coupled to a common plate PL.

In some embodiments, a peripheral circuit portion may be disposed over the memory cell array MCA. This may be referred to as a “PERI over cell (POC) structure” or a “cell under PERI (CUP) structure”. The peripheral circuit portion may include at least one control circuit that drives the memory cell array MCA. The control circuit of the peripheral circuit portion may include an N-channel transistor, a P-channel transistor, a CMOS circuit, or a combination thereof. The at least one control circuit of the peripheral circuit portion may include an address decoder circuit, a read circuit, and a write circuit. The at least one control circuit of the peripheral circuit portion may include a planar channel transistor, a recessed channel transistor, a buried gate transistor, and a fin channel transistor (FinFET).

For example, the peripheral circuit portion may include sub-word line drivers and a sense amplifier. The second conductive lines WL may be coupled to the sub-word line drivers. The first conductive line BL may be coupled to the sense amplifier.

In some embodiments, the peripheral circuit portion may be disposed at a lower level than the memory cell array MCA. This may be referred to as a “PERI under cell (PUC) structure” or a “cell over peripheral (COP) structure”.

In some embodiments, the memory cell array MCA may include DRAM, embedded DRAM, NAND, FeRAM, STT-RAM, PCRAM, or ReRAM.

In an embodiment, the semiconductor device 200 may include a column array and a row array of the nano sheets HL, the second conductive lines WL surrounding in common the nano sheets HL of the row array and each surrounding the nano sheets HL of the column array, the data storage elements CAP coupled to the nano sheets HL of the column array and the row array, respectively, and the first conductive lines BL coupled in common to the nano sheets HL of the column array. Each of the first conductive lines BL may include the first vertical conductive line BLA and the second vertical conductive line BLB. The first vertical conductive line BLA and the second vertical conductive line BLB may be formed through a mask and etching process.

The first conductive line BL of the memory cell array MCA may be in direct contact with the blocking layer WBR. A dielectric layer DE of the data storage element CAP of the memory cell array MCA may be in direct contact with the blocking layer WBR.

A bridge between the first conductive lines BL disposed adjacent to each other in the third direction D3 may be prevented by the blocking layer WBR. In addition, a bridge between the first conductive line BL and the data storage element CAP may be prevented by the blocking layer WBR.

From another perspective, the semiconductor device 200 may include the first sub-cell array MCA1 including the first memory cells MC1 vertically stacked, the second sub-cell array MCA2 including the second memory cells MC2 vertically stacked, and a linear opening (refer to reference symbol “LO” in FIG. 3) between the first sub-cell array MCA1 and the second sub-cell array MCA2. Further, the semiconductor device 200 may include the first conductive line BL formed in the linear opening LO and electrically coupled to the first and second memory cells MC1 and MC2 horizontally disposed adjacent to each other.

From another perspective, the semiconductor device 200 may include the first conductive line BL vertically oriented in the first direction D1, and the data storage element CAP horizontally spaced apart from the first conductive line BL. Further, the semiconductor device 200 may include the nano sheet HL horizontally oriented in the second direction D2 perpendicular to the first direction D1 and including the first region NS contacting the first conductive line BL and the second region WS contacting the data storage element CAP. Furthermore, the semiconductor device 200 may include the second conductive line WL extending while surrounding the nano sheet HL in the third direction D3 perpendicular to the first and second directions D1 and D3.

From another perspective, the semiconductor device 200 may include a vertical stack including the column array AR1 of nano sheet transistors TR vertically stacked in the first direction D1. Each of the nano sheet transistors TR may include a flat plate-shaped narrow sheet NS and a fan-shaped wide sheet WS having a horizontal length less than the flat plate-shaped narrow sheet NS. Each of the nano sheet transistors TR may further include the nano sheet HL extending in the second direction D2 perpendicular to the first direction D1, and the second conductive line WL surrounding the flat plate-shaped narrow sheet NS and horizontally oriented in the third direction D3 perpendicular to the first and second directions D1 and D2.

From another perspective, the semiconductor device 200 may include a first column array MCA1 of the nano sheet transistors TR vertically stacked in the first direction D1, and a second column array MCA2 of the nano sheet transistors TR horizontally spaced apart from the first column array MCAL and vertically stacked in the first direction D1. Further, the semiconductor device 200 may include the vertical conductive line BL sharing the nano sheet transistors TR of the first column array MCA1 and the nano sheet transistors TR of the second column array MCA2 and extending in the first direction D1, and the data storage elements CAP coupled to the nano sheet transistors TR of the first and second column arrays MCA1 and MCA2. Each of the nano sheet transistors TR may include a flat plate-shaped narrow sheet NS and a fan-shaped wide sheet WS having a horizontal length less than the flat plate-shaped narrow sheet NS. Each of the nano sheet transistors TR may further include the nano sheet HL extending in the second direction D2 perpendicular to the first direction D1, and the second conductive line WL surrounding the flat plate-shaped narrow sheet NS and horizontally oriented in the third direction D3 perpendicular to the first and second directions D1 and D2. The second conductive lines WL of the first and second column arrays MCA1 and MCA2 may extend in the third direction D3 while surrounding the nano sheets HL disposed at the same horizontal level.

As described above, because the semiconductor device 200 includes the SOI structure including the blocking layer WBR, wet resistance of the substrate W10 may be enhanced. In the recess processes for securing an outer diameter of the first electrode SN of the data storage element CAP, a substrate bunker may be prevented. As the outer diameter of the first electrode SN is secured, capacitance increases, and cell density may be improved. Because the substrate bunker is prevented, leakage between the dielectric layer DE of the data storage element CAP and the substrate W10 may be prevented, and wafer stability in the subsequent packaging process may be enhanced.

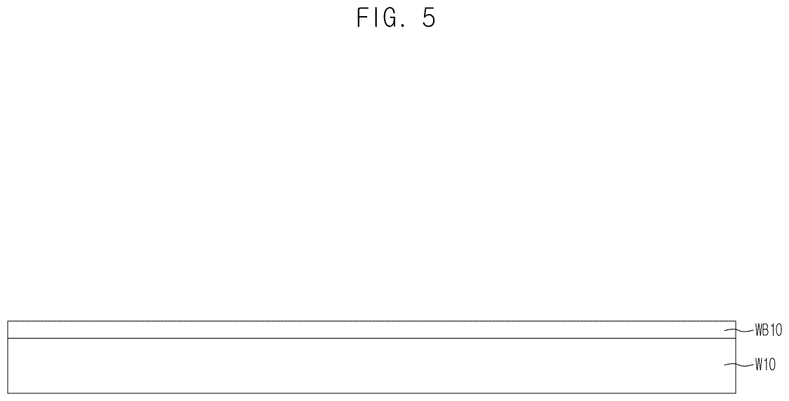

FIGS. 5 to 7 illustrate various views of a mold stack structure formed utilizing a method for fabricating the mold stack structure in accordance with an embodiment of the present disclosure.

As illustrated in FIG. 5, a first bonding dielectric layer WB10 may be formed on a substrate W10. The substrate W10 may be a material appropriate for semiconductor processing. The substrate W10 may include one or more of a conductive material, a dielectric material and a semiconductive material. The substrate W10 may include silicon, monocrystalline silicon, polysilicon, amorphous silicon, silicon germanium, monocrystalline silicon germanium, polycrystalline silicon germanium, carbon-doped silicon, a combination thereof, or multilayers thereof. The substrate W10 may also include another semiconductor material such as germanium. The substrate W10 may also include a III-V group semiconductor substrate, for example, a compound semiconductor substrate such as GaAs. The first bonding dielectric layer WB10 may include an oxide-based material such as silicon oxide.

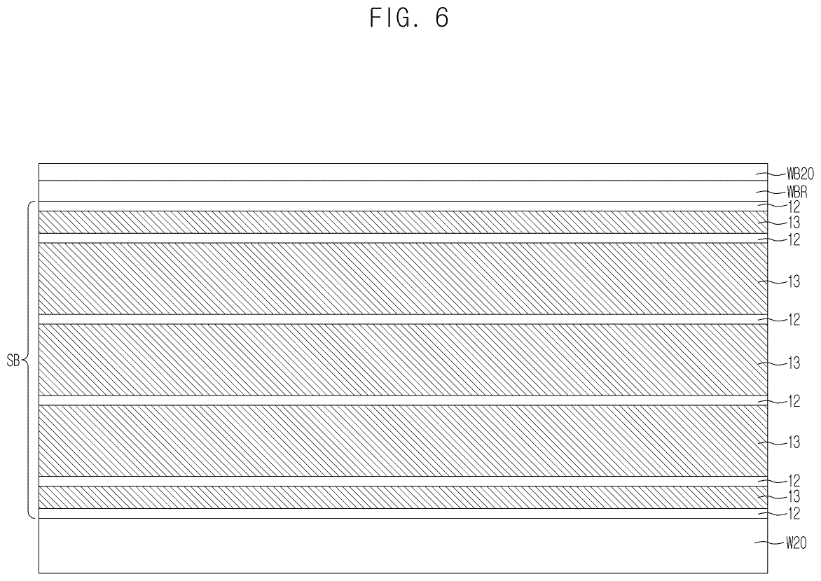

Referring to FIG. 6, a mold stack SB may be formed on a sacrificial substrate W20. The mold stack SB may include an alternating stack of first mold layers 12 and second mold layers 13.

The first mold layers 12 may be alternately stacked with the second mold layers 13. The first mold layers 12 and the second mold layers 13 may be epitaxially grown multiple times, to form the mold stack SB. In the mold stack SB, alternating layers of the first mold layer 12 and the second mold layer 13 may be repeatedly grown to form multi-level tiers such as tier 1, tier 2, and tier 3. Each of the tiers may include a two-layer structure of the first mold layer 12 and the second mold layer 13. The first mold layer 12 may be disposed at the top of the mold stack SB.

The first mold layers 12 and the second mold layers 13 may be different semiconductor materials. The first mold layers 12 may include silicon germanium or monocrystalline silicon germanium. The second mold layers 13 may include monocrystalline silicon. The first mold layers 12 and the second mold layers 13 may be formed by an epitaxial growth process. The lowermost first mold layer 12 may serve as a seed layer during the epitaxial growth process. Each of the first mold layers 12 may be thinner than each of the second mold layers 13. The first mold layers 12 may include first epitaxially grown layers, and the second mold layers 13 may include second epitaxially grown layers.

In an embodiment, a plurality of monocrystalline silicon germanium layers may be alternately stacked with a plurality of monocrystalline silicon layers in the mold stack SB. For example, the first mold layers 12 may be the monocrystalline silicon germanium layers, and the second mold layers 13 may be the monocrystalline silicon layers. A stack of a monocrystalline silicon germanium layer and a monocrystalline silicon layer (a SiGe/Si stack) may be stacked multiple times. The first mold layers 12 may be referred to as “sacrificial layers”, and the second mold layers 13 may be referred to as “nano sheet target layers” or “recess target layers”.

The mold stack SB may be referred to as a “vertical stack”. The mold stack SB may be formed by alternately stacking a plurality of sacrificial layers and a plurality of nano sheet target layers. The sacrificial layers may be monocrystalline silicon germanium layers, and the nano sheet target layers may be monocrystalline silicon layers.

A thickness ratio of the first mold layers 12 and the second mold layers 13 in the mold stack SB may be variously modified. For example, the thickness of the first mold layers 12 may be approximately 5 to 20 nm, and the thickness of the second mold layers 13 may be approximately 50 to 80 nm. The quantity of alternately stacking of the first mold layers 12 and the second mold layers 13 in the mold stack SB may be variously modified. In some embodiments, a triple stack including the first mold layer 12, the second mold layer 13, and the first mold layer 12 may be defined at the lowermost and/or uppermost portions of the mold stack SB. The second mold layer 13 of the triple stack may have a thickness less than the second mold layer 13 of the mold stack SB.

A blocking layer WBR may be formed on the mold stack SB. A second bonding dielectric layer WB20 may be formed on the blocking layer WBR.

The blocking layer WBR may have an etch selectivity with respect to the first mold layers 12 and the second mold layers 13. The blocking layer WBR may have an etch selectivity with respect to the first and second bonding dielectric layers WB10 and WB20. The blocking layer WBR may include a dielectric material. The blocking layer WBR may include a carbon-containing material. The blocking layer WBR may include a dielectric material containing carbon of approximately 5 to 15 at %. A carbon content may be adjusted for a wet barrier function and a leakage suppression effect.

The blocking layer WBR may include silicon carbon oxide (SiCO). A carbon content of the silicon carbon oxide (SiCO) may be approximately 5 to 15 at %. The carbon content has good leakage suppression characteristics and an etch rate close to approximately 0. A thickness of the blocking layer WBR may be approximately 100 to 500 Å. In some embodiments, the blocking layer WBR may include SiCN (a carbon content of approximately 18 to 25 at %). In some embodiments, the blocking layer WBR may have a carbon content of 5 to 60 at %. In some embodiments, the blocking layer WBR may include an alternating stack of a plurality of silicon carbon oxide layers and a plurality of silicon carbon nitride layers.

The second bonding dielectric layer WB20 may include an oxide-based material such as silicon oxide. The first bonding dielectric layer WB10 and the second bonding dielectric layer WB20 may be the same material.

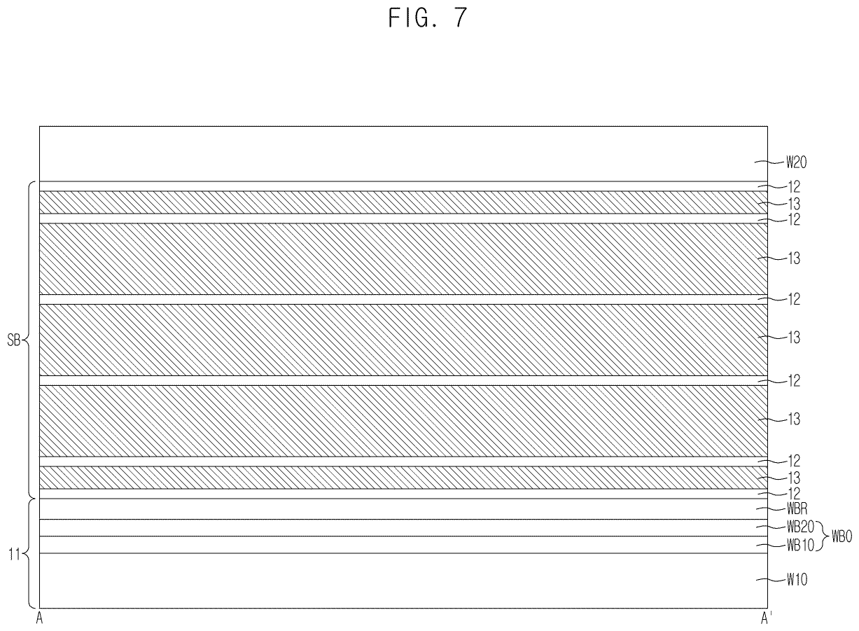

Referring to FIG. 7, the first bonding dielectric layer WB10 and the second bonding dielectric layer WB20 may be bonded. For example, the resultant sacrificial substrate W20 of FIG. 6 may be flipped so that the second bonding dielectric layer WB20 is disposed at the lowermost level. The process of flipping the sacrificial substrate W20 on which the mold stack SB and the blocking layer WBR are formed may be referred to as a “wafer flip” or a “substrate flip”.

The mold stack structure including a lower structure 11, the mold stack SB and the sacrificial substrate W20 may be formed by the wafer flip.

The lower structure 11 may include a stack of the substrate W10, the first bonding dielectric layer WB10, the second bonding dielectric layer WB20, and the blocking layer WBR. The mold stack SB may be disposed over the lower structure 11. The sacrificial substrate W20 may be disposed over the mold stack SB. Specifically, the first bonding dielectric layer WB10, the second bonding dielectric layer WB20, the blocking layer WBR, the mold stack SB, and the sacrificial substrate W20 may be sequentially stacked on the substrate W10.

The first bonding dielectric layer WB10 and the second bonding dielectric layer WB20 may be bonded by a wafer bonding process, and thus a bonding dielectric layer WBO may be formed. The first bonding dielectric layer WB10 and the second bonding dielectric layer WB20 may be bonded by oxide-to-oxide bonding. The bonding dielectric layer WBO may include a stack of the first bonding dielectric layer WB10 and the second bonding dielectric layer WB20.

As a comparative example, an SOI substrate without a bonding dielectric layer WBO and the blocking layer WBR may be used alone. The mold stack SB may be formed over the SOI substrate. However, in the comparative example, only a silicon layer may be deposited on oxide of the SOI substrate. Therefore, when other materials such as a silicon germanium layer are deposited, the silicon layer has to be removed before the silicon germanium layer is deposited. In addition, in the comparative example, the silicon layer has to be deposited on the oxide of the SOI substrate, and the silicon germanium layer has to be deposited on the silicon layer.

In an embodiment, because the bonding dielectric layer WBO and the blocking layer WBR are formed, there is no limitation on the deposition of a silicon germanium layer for the mold stack SB.

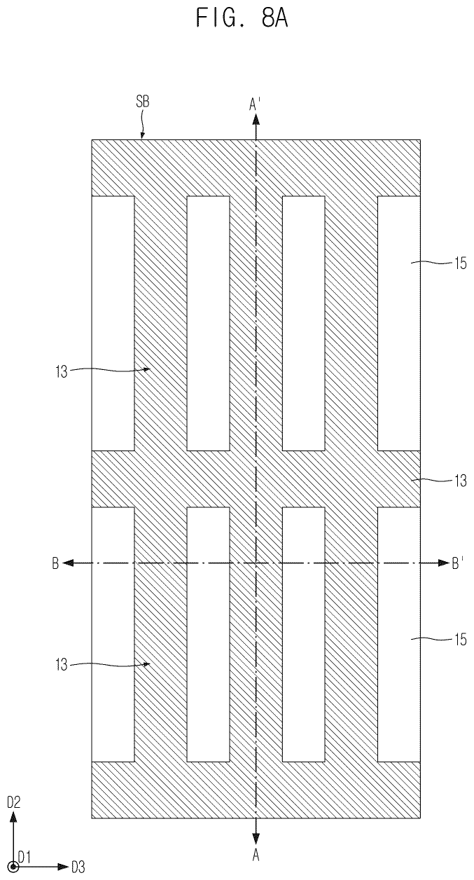

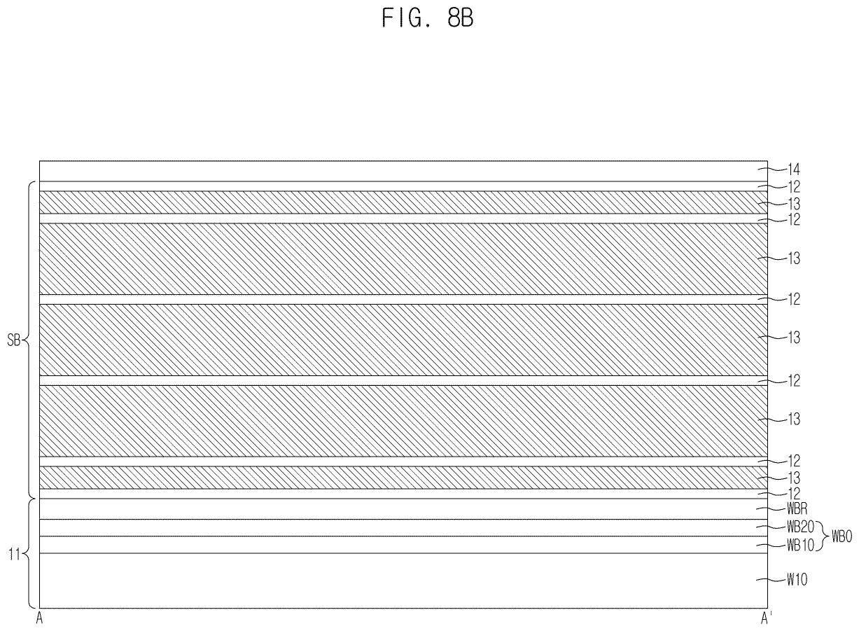

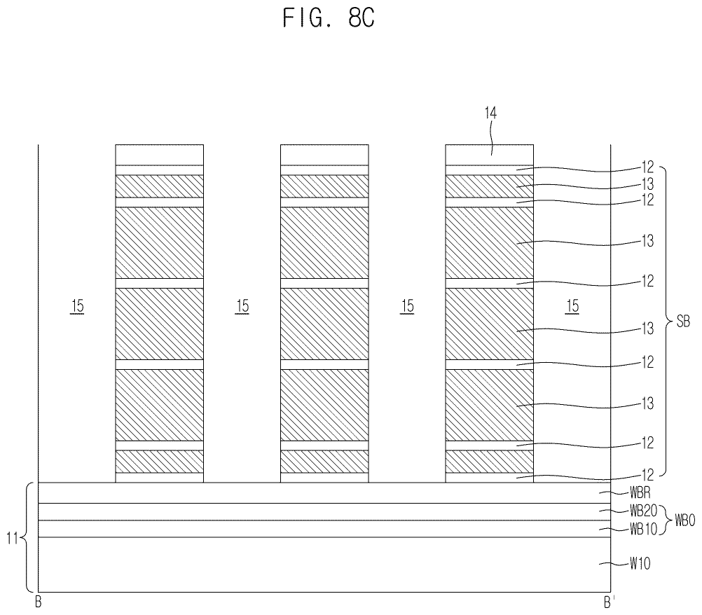

After the lower structure 11 and the mold stack SB are formed through the method described with reference to FIGS. 5 to 7, a memory cell array of a semiconductor device may be formed. Hereinafter, a method for manufacturing the memory cell array is described with reference to FIGS. 8A to 26B.

FIGS. 8A to 26B illustrate various views of a semiconductor device formed utilizing the method for fabricating the memory cell array in accordance with an embodiment of the present disclosure.

FIG. 8A is a plan view illustrating a structure at a second mold layer level to describe a method for forming sacrificial isolation openings 15. FIG. 8B is a cross-sectional view illustrating the structure taken along line A-A′ illustrated in FIG. 8A. FIG. 8C is a cross-sectional view illustrating the structure taken along line B-B′ illustrated in FIG. 8A.

Referring to FIGS. 8A to 8C, after the sacrificial substrate W20 illustrated in FIG. 7 is removed, a first hard mask layer 14 may be formed on the mold stack SB. The sacrificial substrate W20 may be removed by a chemical mechanical polishing (CMP) process, thereby exposing the first mold layer 12 at the uppermost level of the mold stack SB before forming the first hard mask layer 14. The first hard mask layer 14 may include a dielectric material, such as an oxide-based material, a nitride-based material, a carbon-based material, or a combination thereof. For example, the first hard mask layer 14 may include SiO₂, Si₃N₄, amorphous carbon, or a combination thereof.

Subsequently, portions of the mold stack SB may be etched using the first hard mask layer 14 as a barrier, and a plurality of sacrificial isolation openings 15 may be formed. The sacrificial isolation openings 15 may be initial openings for cell isolation. From the perspective of a top view, cross-sections of the sacrificial isolation openings 15 may each have a rectangular shape. In some embodiments, the cross-sections of the sacrificial isolation openings 15 may each have a circular shape or an oval shape. In some embodiments, the sacrificial isolation openings 15 may be referred to as “sacrificial isolation trenches”. The sacrificial isolation openings 15 may vertically extend in a first direction D1 and extend lengthwise in a second direction D2. The sacrificial isolation openings 15 may be disposed at a regular interval in a third direction D3.

An etch process for forming the sacrificial isolation openings 15 may stop at the blocking layer WBR.

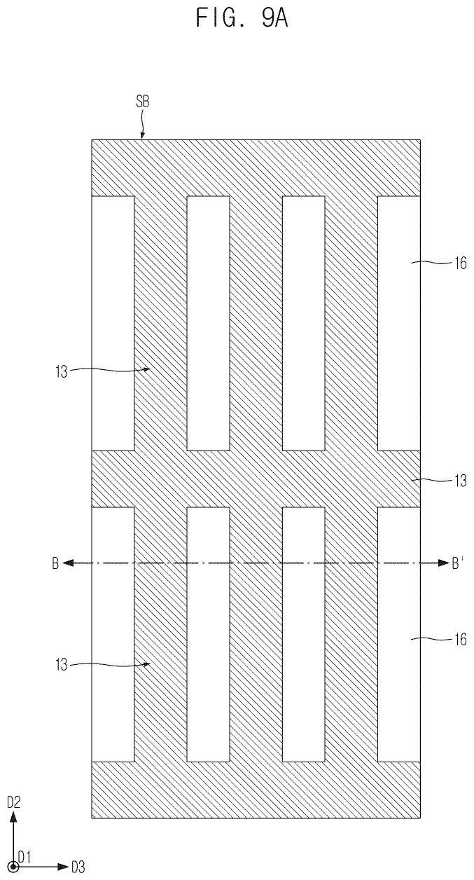

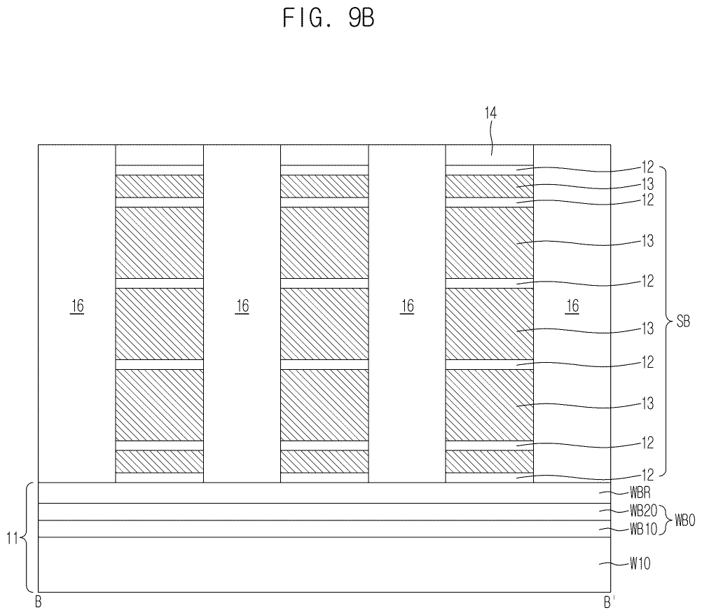

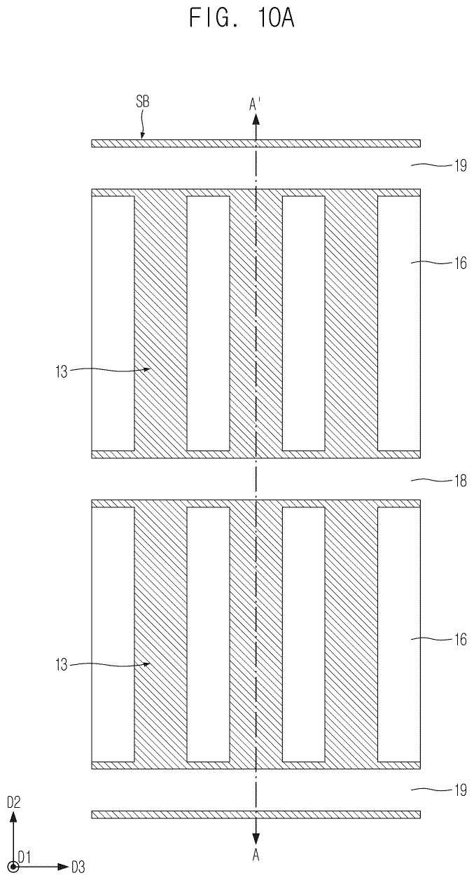

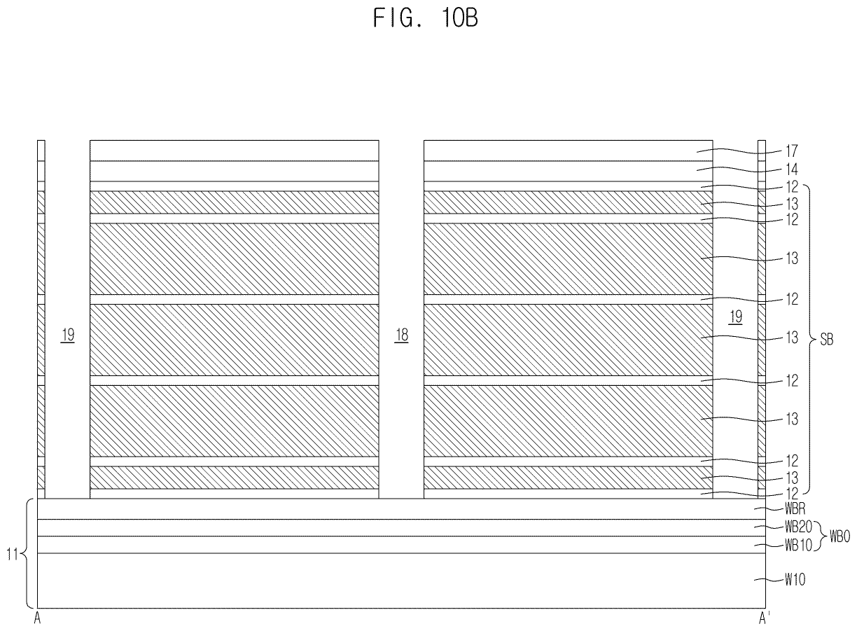

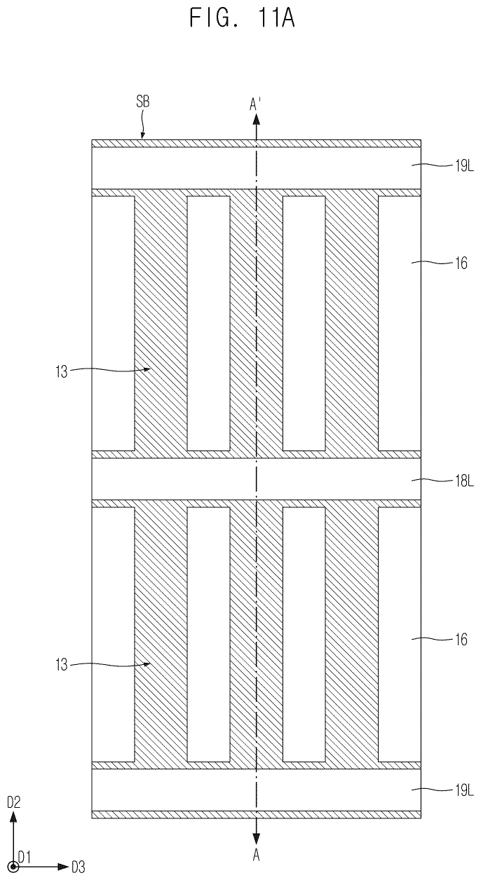

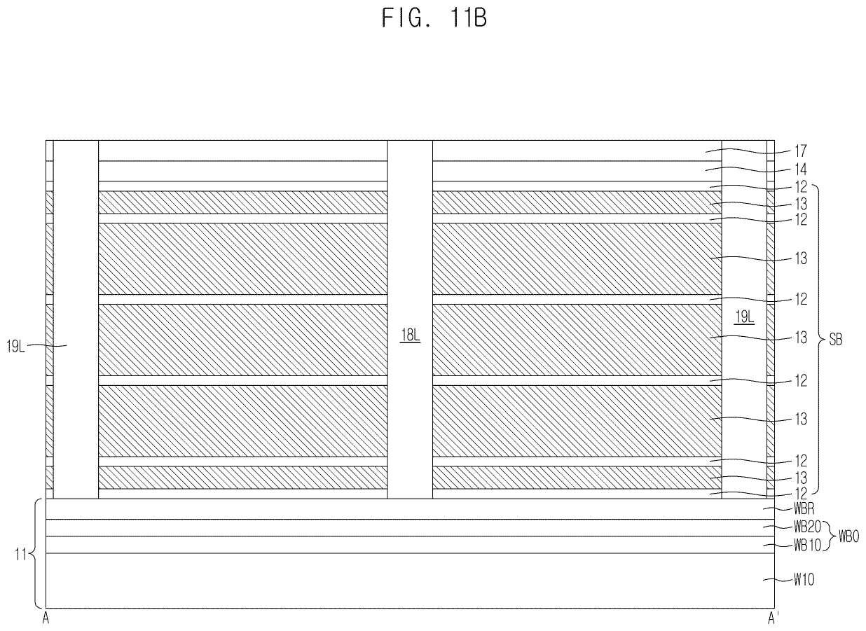

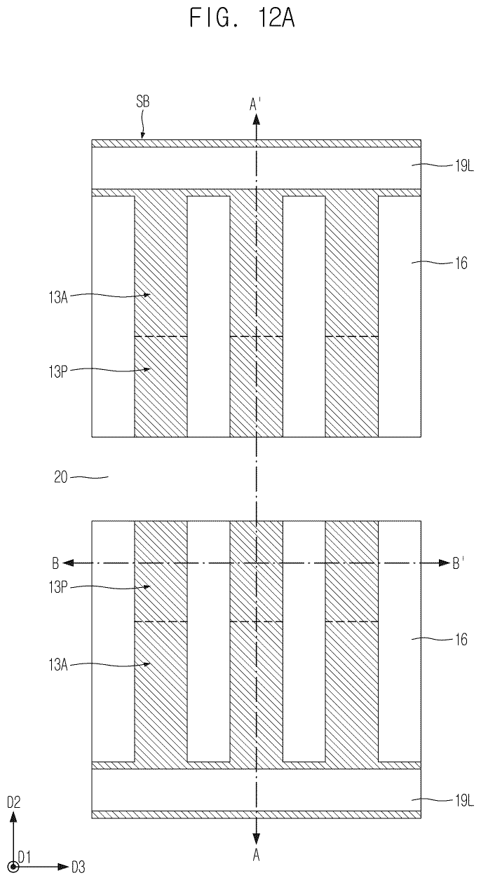

FIG. 9A is a plan view illustrating the structure at the second mold layer level to describe a method for forming sacrificial isolation layers 16, and FIG. 9B is a cross-sectional view illustrating the structure taken along line B-B′ illustrated in FIG. 9A.

Referring to FIGS. 9A and 9B, the sacrificial isolation layers 16 may be formed to fill the sacrificial isolation openings 15. The sacrificial isolation layers 16 may include the same material. The sacrificial isolation layers 16 may be formed of a dielectric material. The sacrificial isolation layers 16 may have an etch selectivity with respect to the mold stack SB. For example, the sacrificial isolation layers 16 may each include silicon oxide, silicon nitride, silicon carbon oxide, silicon carbon nitride, or a combination thereof. Forming the sacrificial isolation layers 16 may include forming sacrificial isolation materials on the first hard mask layer 14 to fill the sacrificial isolation openings 15 and planarizing the sacrificial isolation materials so that a surface of the first hard mask layer 14 is exposed.

The sacrificial isolation layers 16 may vertically extend in the first direction D1 and extend lengthwise in the second direction D2. The sacrificial isolation layers 16 may be disposed at a predetermined interval in the third direction D3. Each of the sacrificial isolation layers 16 may include a stack of a first sacrificial liner layer and a first sacrificial gap-fill layer. The first sacrificial liner layer may be silicon nitride, and the first sacrificial gap-fill layer may be silicon oxide. Bottom surfaces of the sacrificial isolation layers 16 may contact the blocking layer WBR. The sacrificial isolation layers 16 may penetrate the stack body SB in the first direction D1.

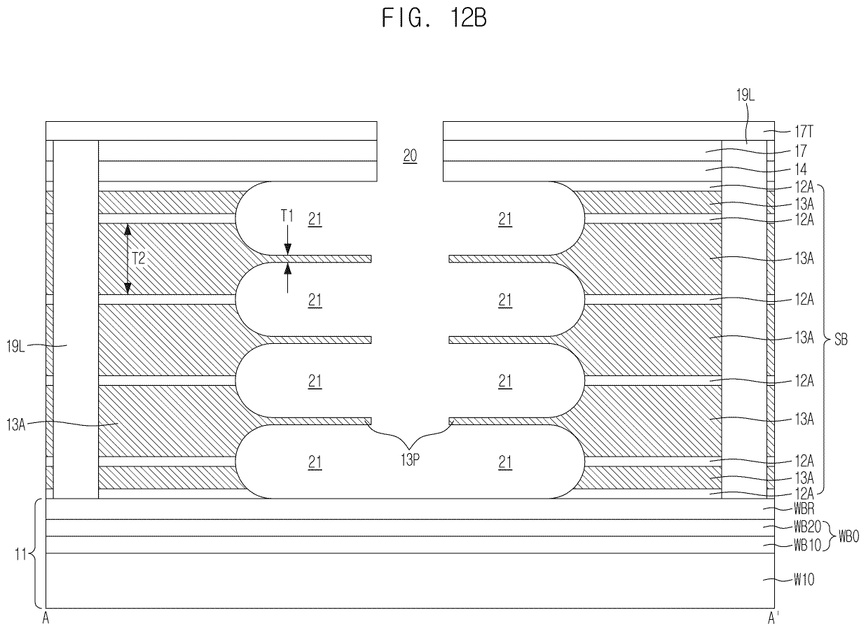

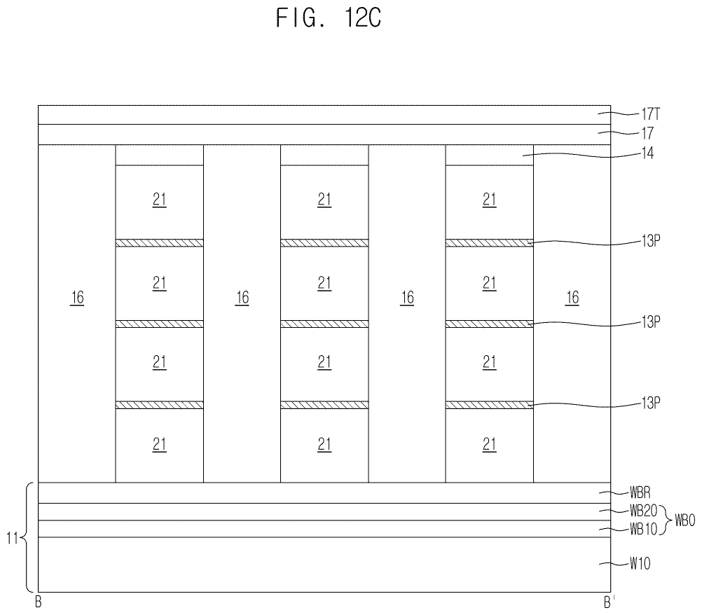

FIG. 10A is a plan view illustrating the structure at the second mold layer level to describe a method for forming sacrificial linear openings 18 and 19, and FIG. 10B is a cross-sectional view illustrating the structure taken along line B-B′ illustrated in FIG. 10A.

Referring to FIGS. 10A and 10B, a second hard mask layer 17 may be formed on the first hard mask layer 14 and the sacrificial isolation layers 16. The second hard mask layer 17 may include silicon nitride. The second hard mask layer 17 may be formed by etching a second hard mask material using a mask layer such as photoresist. The second hard mask layer 17 may have a plurality of line-shaped openings defined therein.

The first hard mask layer 14 may be etched using the second hard mask layer 17 as an etch barrier, and subsequently, portions of the mold stack SB may be etched. Accordingly, a plurality of sacrificial linear openings 18 and 19 may be formed between the sacrificial isolation layers 16. The sacrificial linear openings may include a first sacrificial linear opening 18 and a second sacrificial linear opening 19. From the perspective of a top view, the first sacrificial linear opening 18 and the second sacrificial linear opening 19 may be line-shaped openings extending in the third direction D3. The first sacrificial linear opening 18 and the second sacrificial linear opening 19 may vertically extend in the first direction D1. The sacrificial isolation layers 16 may be disposed between the first sacrificial linear opening 18 and the second sacrificial linear opening 19 in the second direction D2. From the perspective of a top view, cross sections of the first and second sacrificial linear openings 18 and 19 may each have a rectangular shape. In some embodiments, the cross sections of the first and second sacrificial linear openings 18 and 19 may each have a circular shape or an oval shape. The first and second sacrificial linear openings 18 and 19 may each have a width in the second direction D2 less than a width in the third direction D3. The first and second sacrificial linear openings 18 and 19 may be referred to as “sacrificial linear trenches”. The sacrificial isolation layers 16 may not contact the first and second sacrificial linear openings 18 and 19.

Bottom surfaces of the first and second sacrificial linear openings 18 and 19 may expose the blocking layer WBR.

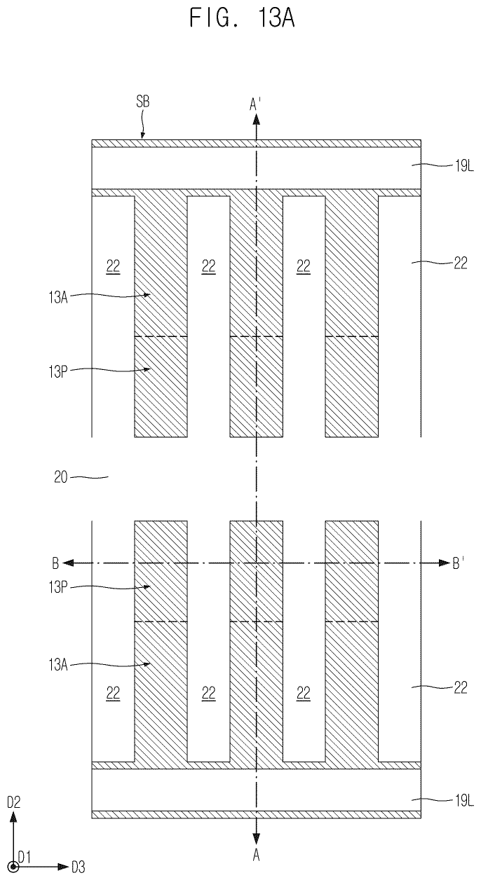

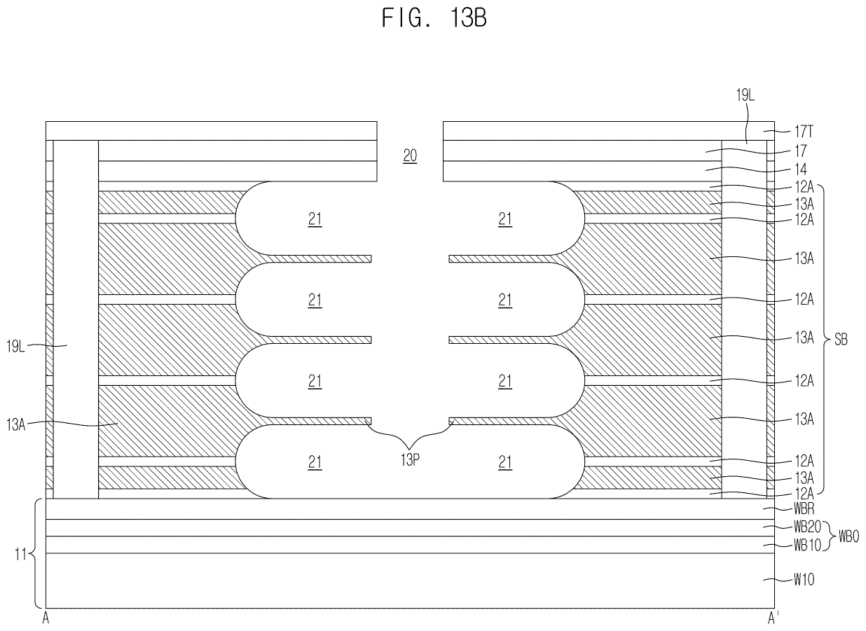

FIG. 11A is a plan view illustrating the structure at the second mold layer level to describe a method for forming linear sacrificial layers 18L and 19L, and FIG. 11B is a cross-sectional view illustrating the structure taken along line A-A′ illustrated in FIG. 11A.

Referring to FIGS. 11A and 11B, the linear sacrificial layers 18L and 19L may be formed to fill the first and second sacrificial linear openings 18 and 19 of FIGS. 10A and 10B. The linear sacrificial layers may include a first linear sacrificial layer 18L and a second linear sacrificial layer 19L. From the perspective of a top view, the first linear sacrificial layer 18L and the second linear sacrificial layer 19L may have line shapes extending in the third direction D3. The first linear sacrificial layer 18L and the second linear sacrificial layer 19L may vertically extend in the first direction D1. The sacrificial isolation layers 16 may be disposed between the first linear sacrificial layer 18L and the second linear sacrificial layer 19L in the second direction D2. From the perspective of a top view, cross sections of the first and second linear sacrificial layers 18L and 19L may each have a rectangular shape. In some embodiments, the cross-sections of the first and second linear sacrificial layers 18L and 19L may each have a circular shape or an oval shape. The first and second linear sacrificial layers 18L and 19L may include the same material. The first and second linear sacrificial layers 18L and 19L may be formed of a dielectric material. For example, the first and second linear sacrificial layers 18L and 19L may each include silicon oxide, silicon nitride, silicon carbon oxide, silicon carbon nitride, or a combination thereof. The sacrificial isolation layers 16 may not contact the first and second linear sacrificial layers 18L and 19L.

Bottom surfaces of the first and second linear sacrificial layers 18L and 19L may contact the blocking layer WBR.

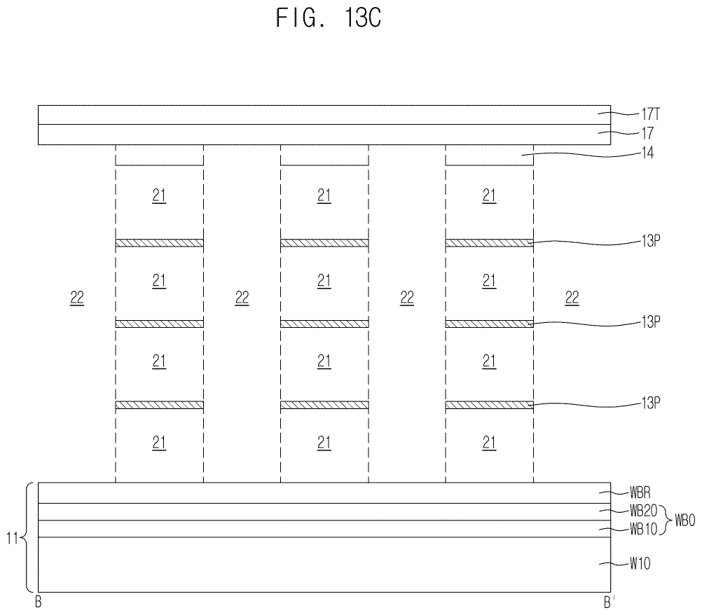

FIG. 12A is a plan view illustrating the structure at the second mold layer level to describe partial recessing of the first and second mold layers 12 and 13, and FIG. 12B is a cross-sectional view illustrating the structure taken along line A-A′ illustrated in FIG. 12A. FIG. 12C is a cross-sectional view illustrating the structure taken along line B-B′ illustrated in FIG. 12A.

Referring to FIGS. 12A to 12C, among the first linear sacrificial layer 18L and the second linear sacrificial layer 19L of FIGS. 11A and 11B, the first linear sacrificial layer 18L may be selectively removed. A third hard mask layer 17T may be used as an etch barrier to remove the first linear sacrificial layer 18L. Accordingly, a first linear opening 20 may be formed. A bottom surface of the first linear opening 20 may expose the blocking layer WBR. From the perspective of a top view, the first linear opening 20 may be disposed horizontally spaced apart from the second linear sacrificial layer 19L in the second direction D2.

The first linear opening 20 may have the same size as the first sacrificial linear opening 18 described with reference to FIG. 10A. A bottom surface of the first linear opening 20 may be at the same level as a bottom surface of the first sacrificial linear opening 18. The bottom surface of the first linear opening 20 may be at the same level as a bottom surface of the sacrificial isolation opening 15.

Subsequently, the first mold layers 12 may be selectively recessed through the first linear openings 20. To selectively recess the first mold layers 12, a difference in etch selectivity between the first mold layers 12 and the second mold layers 13 may be used. The first mold layers 12 may be removed using a wet etch process or a dry etch process. For example, when the first mold layers 12 include silicon germanium layers, and the second mold layers 13 include monocrystalline silicon layers, the silicon germanium layers may be etched using an etchant or etch gas having a selectivity with respect to the monocrystalline silicon layers. The first mold layers each having an original thickness may remain as indicated by reference numeral “12A”.

Subsequently, portions (first portions) of the second mold layers 13 may be recessed to form narrow sheets 13P. The wet etch process or dry etch process may be used to recess the second mold layers 13. Original body portions 13A and the narrow sheets 13P may be formed by the partial recessing of the second mold layers 13. The original body portions 13A may each maintain an original thickness T1, and the narrow sheets 13P may each have a thickness T2 less than the original thickness T1. Horizontal lengths of the original body portions 13A in the second direction D2 may be equal to or different from horizontal lengths of the narrow sheets 13P in the second direction D2. The combination of each original body portion 13A and each narrow sheet 13P may be referred to as a “preliminary active layer”. The narrow sheets 13P may be referred to as “flat plate-shaped sheets” or “protruding narrow sheets”.

The recess process for forming the narrow sheets 13P may be referred to as a “thinning process” or “trimming process” of the second mold layers 13. To form the narrow sheets 13P, upper surfaces, lower surfaces and side surfaces of the second mold layers 13 may be recessed. The narrow sheets 13P may be referred to as “thin-body active layers”. The narrow sheets 13P may each include a monocrystalline silicon layer. The recess process for forming the narrow sheets 13P may use, for example, Hot SC-1 (HSC1). The HSC1 may include a solution in which ammonium hydroxide (NH₄OH), hydrogen peroxide (H₂O₂), and water (H₂O) are mixed in a ratio of 1:4:20. Using the HSC1, the second mold layers 13 may be selectively etched.

The narrow sheets 13P may be formed by the partial recess process for the second mold layers 13 as described above. Inter-nano sheet recesses 21 may be formed between the narrow sheets 13P that are vertically disposed. Upper and lower surfaces of the narrow sheets 13P may each include a flat surface. A boundary portion between each original body portion 13A and each narrow sheet 13P may be vertical or have a curvature. The first mold layer 12A may be disposed between the original body portions 13A that are vertically stacked.

During the partial recess process for the first and second mold layers 12 and 13, the first bonding dielectric layer WB10, the second bonding dielectric layer WB20 and the substrate W10 may be protected by the blocking layer WBR.

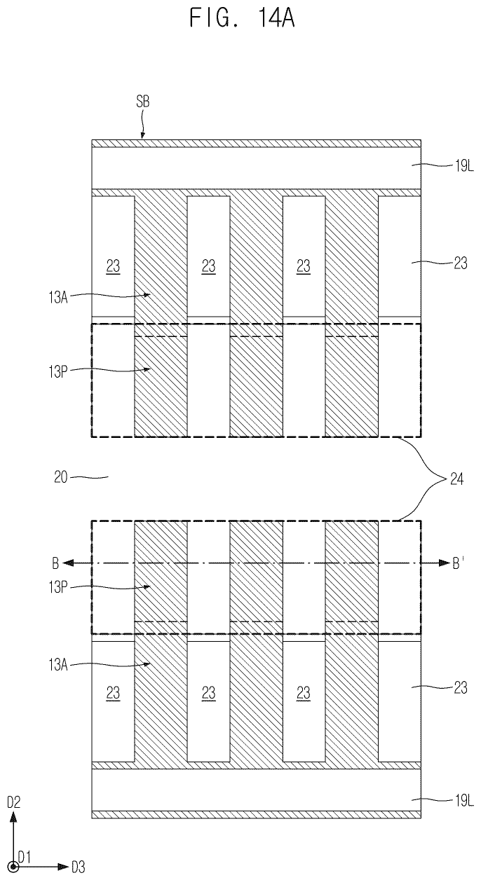

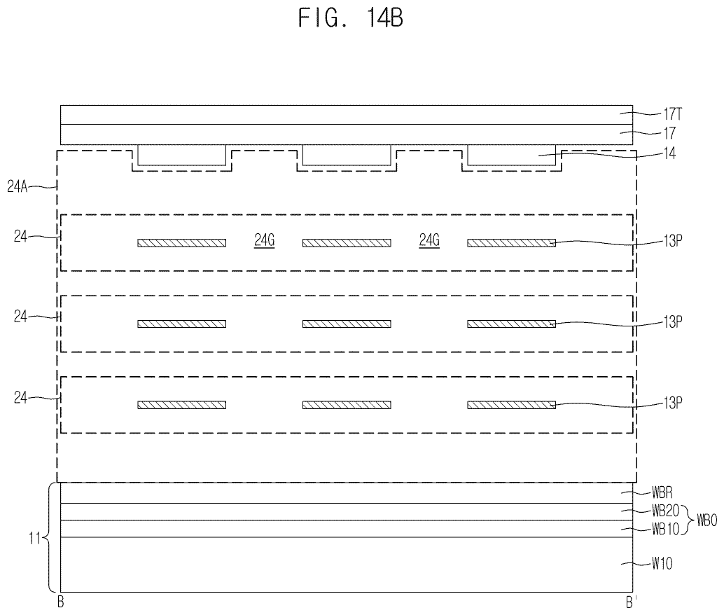

FIG. 13A is a plan view illustrating the structure at a narrow sheet level to describe a method for forming sacrificial isolation layer-level openings 22. FIG. 13B is a cross-sectional view illustrating the structure taken along line A-A′ illustrated in FIG. 13A. FIG. 13C is a cross-sectional view illustrating the structure taken along line B-B′ illustrated in FIG. 13A.

Referring to FIGS. 13A to 13C, the sacrificial isolation layers 16 may be selectively stripped through the inter-nano sheet recesses 21 of FIGS. 12A to 12C. Accordingly, the sacrificial isolation layer-level openings 22 may be formed between the original body portions 13A in the third direction D3.

Side surfaces of the first mold layers 12A, side surfaces of the original body portions 13A, and side surfaces of the narrow sheets 13P may be exposed in the third direction D3 by the sacrificial isolation layer-level openings 22.

In some embodiments, while the sacrificial isolation layer-level openings 22 are formed, a portion of the first hard mask layer 14 may be recessed. Accordingly, a space of the inter-nano sheet recess 21 at the uppermost level may be expanded.

The inter-nano sheet recesses 21 and the sacrificial isolation layer-level openings 22 may be continuous with each other.

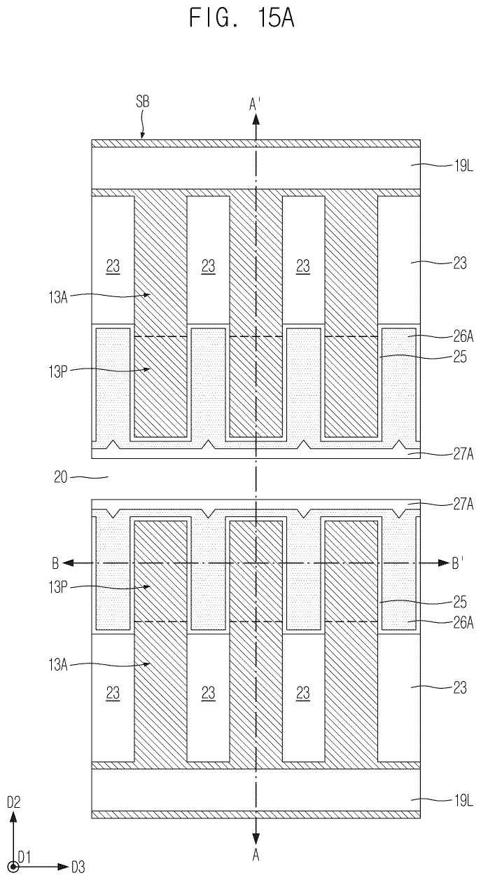

FIG. 14A is a plan view illustrating the structure at the narrow sheet level to describe a method for forming first inter-cell dielectric layers 23. FIG. 14B is a cross-sectional view illustrating the structure taken along line B-B′ illustrated in FIG. 14A.

Referring to FIGS. 14A and 14B, the first inter-cell dielectric layers 23 may be formed in the sacrificial isolation layer-level openings 22 of FIGS. 13A to 13C. The first inter-cell dielectric layers 23 may each include a dielectric material. The first inter-cell dielectric layers 23 may each include silicon oxide, silicon nitride, silicon carbon oxide, or a combination thereof. Forming the first inter-cell dielectric layers 23 may include forming a dielectric material that fills the sacrificial isolation layer-level openings 22 and performing an etch-back process on the dielectric material.

The first inter-cell dielectric layers 23 may fill portions of the sacrificial isolation layer-level openings 22. The side surfaces of the first mold layers 12A and the side surfaces of the original body portions 13A may be covered by the first inter-cell dielectric layers 23 in the third direction D3. The first inter-cell dielectric layers 23 may expose the side surfaces of the narrow sheets 13P. The other portions of the sacrificial isolation layer-level openings 22, i.e., non-gap-filled portions, may expose the side surfaces of the narrow sheets 13P.

After the first inter-cell dielectric layers 23 are formed, a nano sheet all-open recess 24A that opens all of the narrow sheets 13P may be formed. The nano sheet all-open recess 24A may refer to a combination of the inter-nano sheet recesses 21 and the non-gap-filled portions of the sacrificial isolation layer-level openings 22. The nano sheet all-open recess 24A may include a plurality of surrounding recesses 24. The surrounding recesses 24 may expose all of the narrow sheets 13P in the third direction D3. For example, any of the surrounding recesses 24 extending in the third direction D3 may surround all surfaces of the narrow sheets 13P at the same horizontal level.

Each of the surrounding recesses 24 may include a plurality of initial gaps 24G, and the initial gaps 24G may be included between the narrow sheets 13P in the third direction D3.

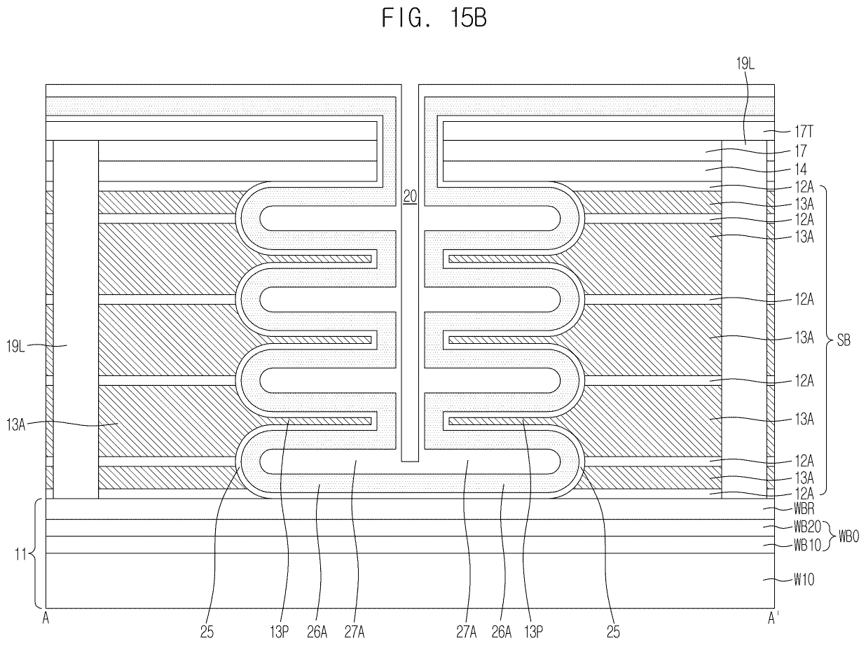

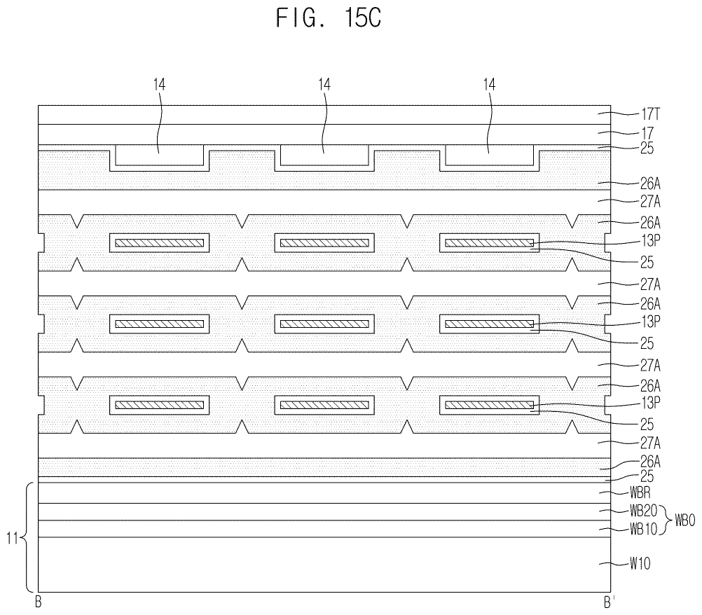

FIG. 15A is a plan view illustrating the structure at the narrow sheet level to describe a method for forming first spacer layers 26A. FIG. 15B is a cross-sectional view illustrating the structure taken along line A-A′ illustrated in FIG. 15A. FIG. 15C is a cross-sectional view illustrating the structure taken along line B-B′ illustrated in FIG. 15A.

Referring to FIGS. 15A to 15C, nano sheet dielectric layers 25 may be formed on exposed portions of the narrow sheets 13P. The nano sheet dielectric layers 25 may be referred to as “gate dielectric layers”.

The nano sheet dielectric layers 25 may be formed by oxidizing the surfaces of the narrow sheets 13P. In some embodiments, the nano sheet dielectric layers 25 may be formed by a deposition process and an oxidation process of silicon oxide. The nano sheet dielectric layers 25 may each include silicon oxide, silicon nitride, metal oxide, metal oxide nitride, metal silicate, a high-k material, a ferroelectric material, an anti-ferroelectric material, or a combination thereof. The nano sheet dielectric layers 25 may each include SiO₂, Si₃N₄, HfO₂, Al₂O₃, ZrO₂, AlON, HfON, HfSiO, HfSiON, or a combination thereof. The nano sheet dielectric layers 25 may be formed on all surfaces of the narrow sheets 13P.

The first spacer layers 26A may be formed on the nano sheet dielectric layers 25. The first spacer layers 26A may each include silicon nitride. The first spacer layers 26A may surround and cover the narrow sheets 13P on the nano sheet dielectric layers 25. Each of the first spacer layers 26A may be thicker than each of the nano sheet dielectric layers 25.

Second inter-cell dielectric layers 27A may be formed on the first spacer layers 26A. The second inter-cell dielectric layers 27A may each include silicon oxide.

As described above, each of the first spacer layers 26A may be disposed between the narrow sheets 13P in the third direction D3.

The nano sheet dielectric layers 25 and the first spacer layers 26A may also be formed on the surface of the blocking layer WBR.

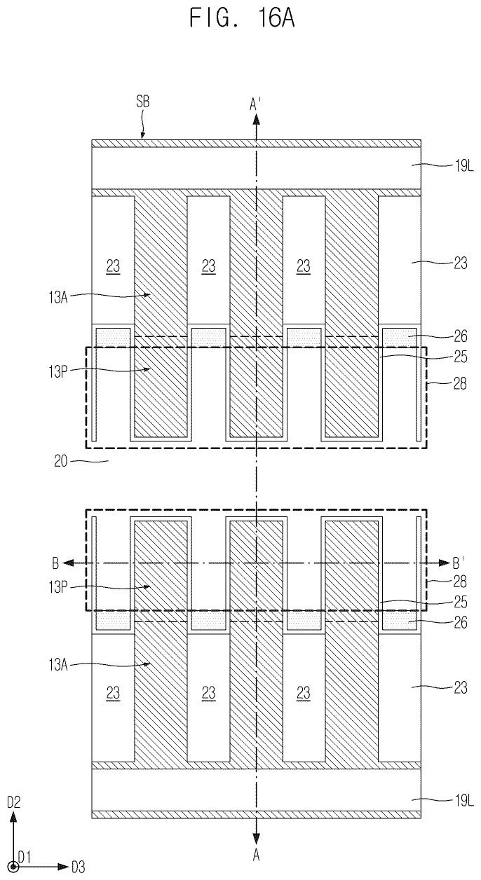

FIG. 16A is a plan view illustrating the structure at the narrow sheet level to describe a method for forming first spacers 26. FIG. 16B is a cross-sectional view illustrating the structure taken along line A-A′ illustrated in FIG. 16A. FIG. 16C is a cross-sectional view illustrating the structure taken along line B-B′ illustrated in FIG. 16A.

Referring to FIGS. 16A to 16C, the second inter-cell dielectric layers 27A of FIGS. 15A to 15C may be cut through the first linear opening 20. Subsequently, the first spacer layers 26A of FIGS. 15A to 15C may be selectively recessed. The remaining first spacer layers may become the first spacers 26, and the second inter-cell dielectric layers may remain as indicated by reference numeral “27”.

As the first spacers 26 are formed, linear surrounding recesses 28 surrounding the narrow sheets 13P may be formed on the nano sheet dielectric layers 25. The second inter-cell dielectric layers 27 may be disposed between the linear surrounding recesses 28 that are vertically disposed. An upper-level dummy horizontal recess 28U may be formed on the second inter-cell dielectric layer 27 at the uppermost level. A lower-level dummy horizontal recess 28L may be formed below the second inter-cell dielectric layer 27 at the lowermost level. The upper-level and lower-level dummy horizontal recesses 28U and 28L may each have a non-surrounding shape, i.e., a flat shape.

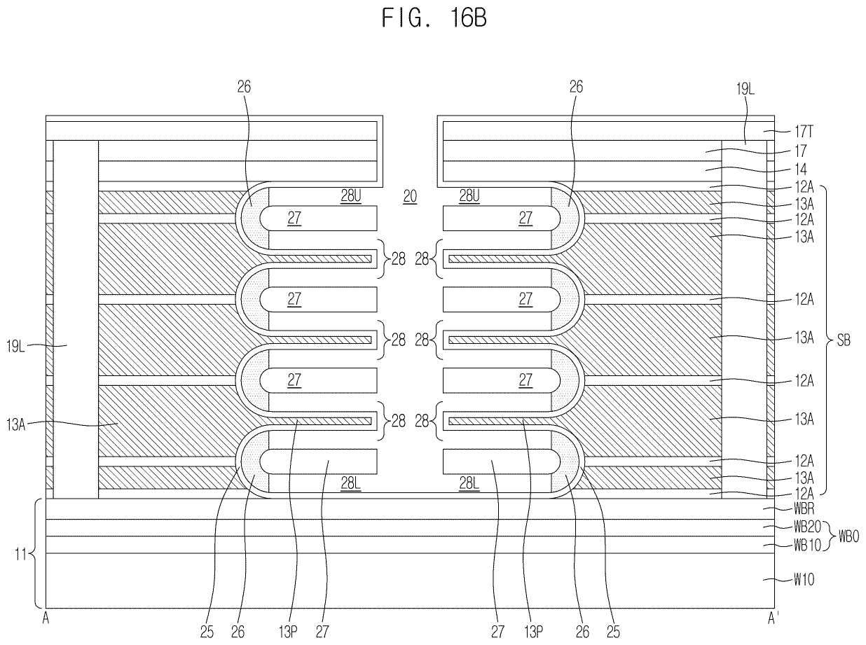

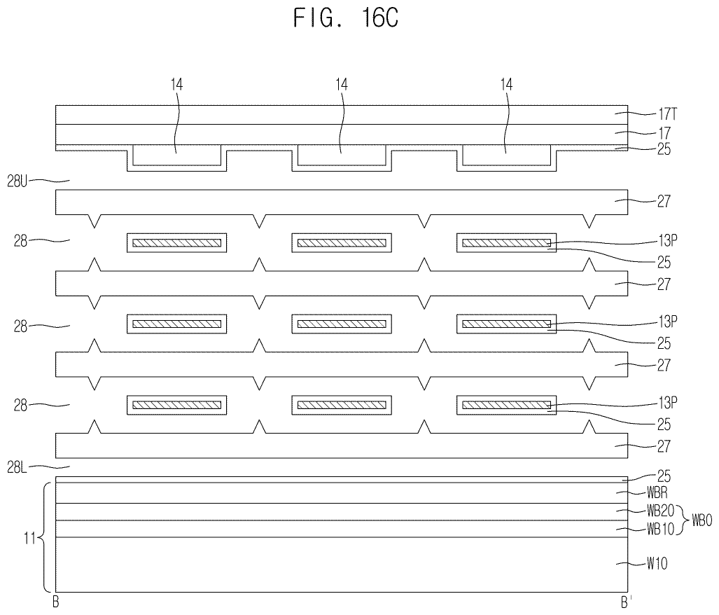

FIG. 17A is a plan view illustrating the structure at the narrow sheet level to describe a method for forming horizontal conductive lines 29. FIG. 17B is a cross-sectional view illustrating the structure taken along line A-A′ illustrated in FIG. 17A. FIG. 17C is a cross-sectional view illustrating the structure taken along line B-B′ illustrated in FIG. 17A.

Referring to FIGS. 17A to 17C, the horizontal conductive lines 29 filling the linear surrounding recesses 28 of FIGS. 16A to 16C may be formed. The horizontal conductive lines 29 may horizontally extend in the third direction D3.

Forming the horizontal conductive lines 29 may include depositing a conductive material filling the linear surrounding recesses 28 on the nano sheet dielectric layers 25 and performing a horizontal etch-back process on the conductive material. Each of the horizontal conductive lines 29 may simultaneously surround the narrow sheets 13P at the same level. The horizontal conductive lines 29 may each include metal, a metal-based material, a semiconductor material, or a combination thereof.

The horizontal conductive lines 29 may each include molybdenum, molybdenum nitride, ruthenium, titanium nitride, tungsten, polysilicon, or a combination thereof. For example, the horizontal conductive lines 29 may each include a titanium nitride and tungsten (TiN/W) stack in which titanium nitride and tungsten are sequentially stacked. The horizontal conductive lines 29 may each include an N-type work function material or a P-type work function material. The N-type work function material may have a low work function of approximately 4.5 eV or less, and the P-type work function material may have a high work function of approximately 4.5 eV or greater. The second inter-cell dielectric layers 27 may be disposed between a plurality of horizontal conductive lines 29 in the first direction D1. The horizontal conductive lines 29 surrounding the narrow sheets 13P may be referred to as “gate-all-around (GAA) electrodes”. The narrow sheets 13P may be referred to as “nano sheet channels”, “nano wires” or “nano wire channels”.

A lower-level dummy horizontal electrode 29L may be formed on the surface of the blocking layer WBR. An upper-level dummy horizontal electrode 29U may be formed over the uppermost horizontal conductive line 29. The lower-level and upper-level dummy horizontal electrodes 29L and 29U may each have a non-surrounding shape.

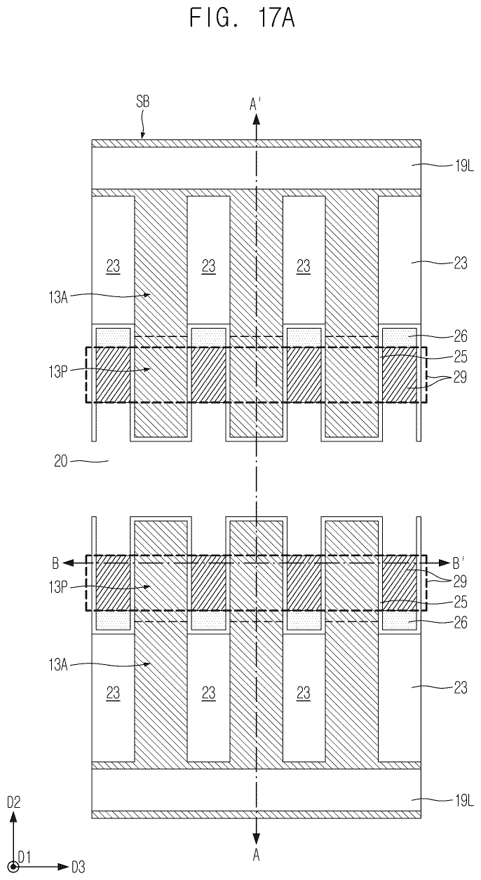

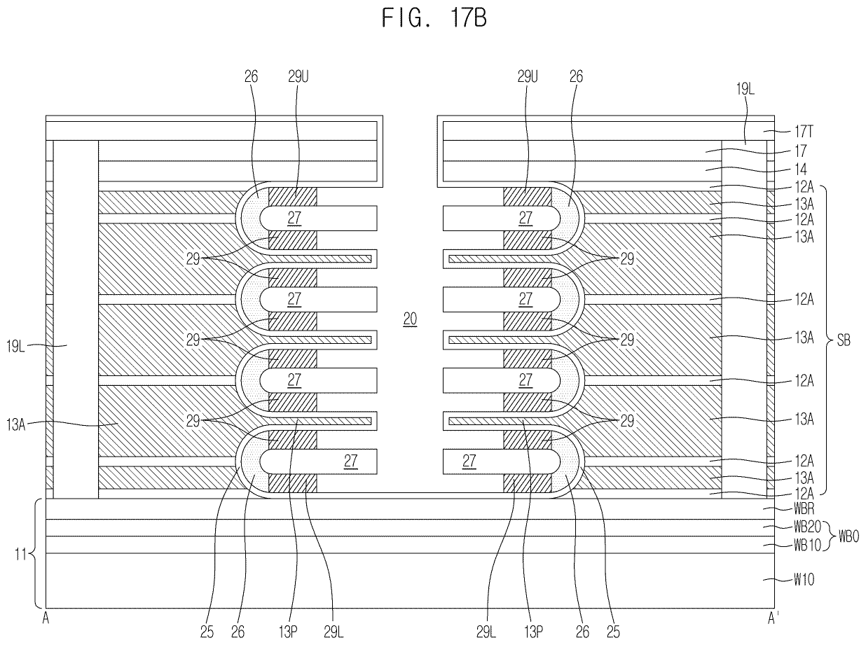

FIG. 18A is a plan view illustrating the structure at the narrow sheet level to describe a method for forming second spacers 30. FIG. 18B is a cross-sectional view illustrating the structure taken along line A-A′ illustrated in FIG. 18A.

Referring to FIGS. 18A and 18B, each of the second spacers 30 may be formed on one side of each of the horizontal conductive lines 29. The second spacer 30 may include silicon oxide, silicon nitride, silicon carbon oxide, an embedded air gap, or a combination thereof. Deposition and etch-back processes of a spacer material may be performed to form the second spacer 30. The second spacer 30 may include a stack of a silicon oxide liner 31A and a silicon nitride liner 31B. A portion of the silicon nitride liner 31B may protrude.

After the second spacer 30 is formed, a portion of the nano sheet dielectric layer 25 may be cut to expose one side of each of the narrow sheets 13P.

The second spacer 30 may be disposed on one side of each of the horizontal conductive lines 29. The second spacers 30 may be disposed on the upper and lower portions of the narrow sheets 13P. A pair of second spacers 30 may correspond to one narrow sheet 13P.

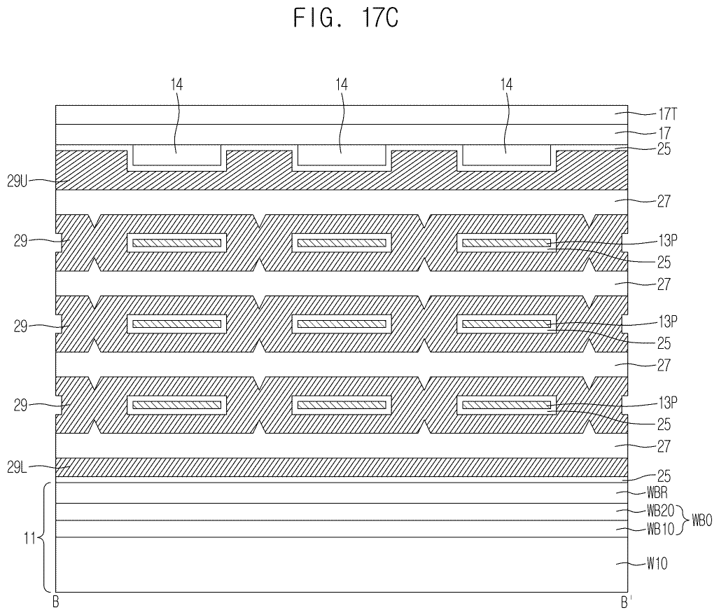

FIG. 19A is a plan view illustrating the structure at the narrow sheet level to describe a method for recessing the narrow sheets 13P. FIG. 19B is a cross-sectional view illustrating the structure taken along line A-A′ illustrated in FIG. 19A.

Referring to FIGS. 19A and 19B, the narrow sheets 13P may be horizontally recessed to form nano sheet level recesses 33. Each of the nano sheet level recesses 33 may be disposed between the second spacers 30 that are vertically stacked. The nano sheet level recess 33 may be an undercut between the second spacers 30 that are vertically stacked.

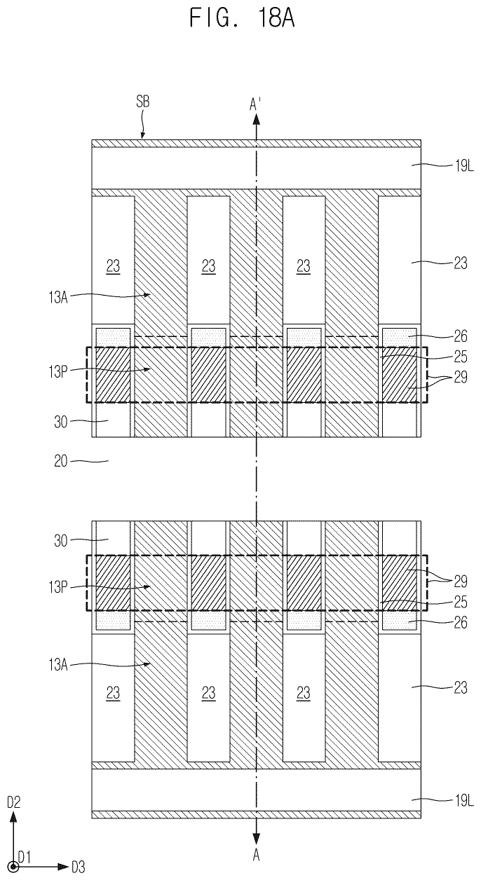

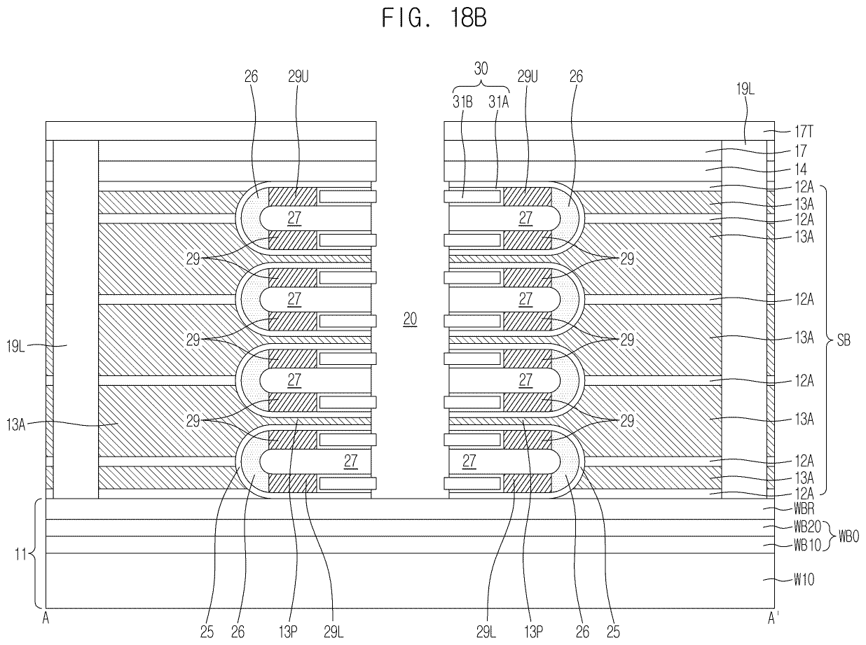

FIG. 20A is a plan view illustrating the structure at the narrow sheet level to describe a method for forming first contact nodes 34. FIG. 20B is a cross-sectional view illustrating the structure taken along line A-A′ illustrated in FIG. 20A.

Referring to FIGS. 20A and 20B, the first contact nodes 34 may be formed to fill the nano sheet level recesses 33 of FIGS. 19A and 19B. Forming the first contact nodes 34 may include depositing a conductive material filling the nano sheet level recesses 33 and performing an etch-back process on the conductive material. The first contact nodes 34 may each include a semiconductor material. The first contact nodes 34 may each include doped polysilicon, and the doped polysilicon may include N-type dopants. Each of the first contact nodes 34 may be disposed between the second spacers 30 that are vertically stacked. The first contact nodes 34 and the second spacers 30 may not be self-aligned in the first direction D1. That is, the first contact nodes 34 may partially fill the undercut between the second spacers 30 that are vertically stacked.

First doped regions 35 may be formed within one side of the narrow sheets 13P. A heat treatment process may be performed to form the first doped regions 35, and thus the dopants may be diffused from the first contact nodes 34. In another method for forming the first doped regions 35, a selective epitaxial growth (SEG) or gas phase doping method may be applied.

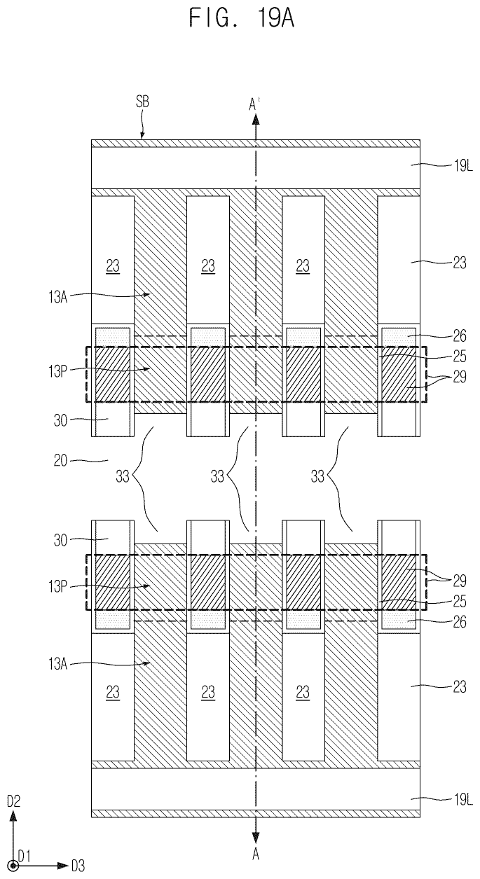

FIG. 21A is a plan view illustrating the structure at the narrow sheet level to describe a method for forming vertical conductive lines 37A and 37B. FIG. 21B is a cross-sectional view illustrating the structure taken along line A-A′ illustrated in FIG. 21A.

Referring to FIGS. 21A and 21B, ohmic contact layers 36 may be formed on the first contact nodes 34. The ohmic contact layers 36 may each include metal silicide.

The vertical conductive lines 37A and 37B may be formed on the ohmic contact layers 36. The vertical conductive lines 37A and 37B may be coupled in common to the ohmic contact layers 36. Accordingly, the vertical conductive lines 37A and 37B may be coupled in common to the narrow sheets 13P disposed in the first direction D1. The vertical conductive lines 37A and 37B may each include a metal-based material. The vertical conductive lines 37A and 37B may each include titanium nitride, tungsten, or a combination thereof.

The deposition and etch processes may be performed on a vertical conductive line material to form the vertical conductive lines 37A and 37B.

Bottom portions 38 of the vertical conductive lines 37A and 37B may be merged with each other. The vertical conductive lines 37A and 37B may be disposed in the first linear opening 20. The vertical conductive lines 37A and 37B may vertically extend in the first direction D1. The bottom portions 38 of the vertical conductive lines 37A and 37B may be merged with each other. The vertical conductive lines 37A and 37B may be coupled in common to the ohmic contact layers 36. Accordingly, the vertical conductive lines 37A and 37B may be coupled in common to the narrow sheets 13P disposed in the first direction D1.

The bottom portions 38 of the vertical conductive lines 37A and 37B may be in direct contact with the blocking layer WBR. Because the blocking layer WBR is disposed between the vertical conductive lines 37A and 37B and the substrate W10, leakage between the vertical conductive lines 37A and 37B and the substrate W10 may be prevented.

As a comparative example, the blocking layer WBR and the bonding dielectric layer WBO may be omitted, and an isolation trench may be formed below the vertical conductive lines 37A and 37B. In this case, the isolation trench may be filled with silicon nitride and Spin On Dielectric (SOD) for electrical isolation between the vertical conductive lines 37A and 37B and the substrate W10. However, there is a concern that the substrate W10 may contact the vertical conductive lines 37A and 37B due to variations in a recess process subsequent to SOD gap-fill.

In an embodiment, because the blocking layer WBR is disposed between the vertical conductive lines 37A and 37B and the substrate W10, the vertical conductive lines 37A and 37B may not come into direct contact with the substrate W10.

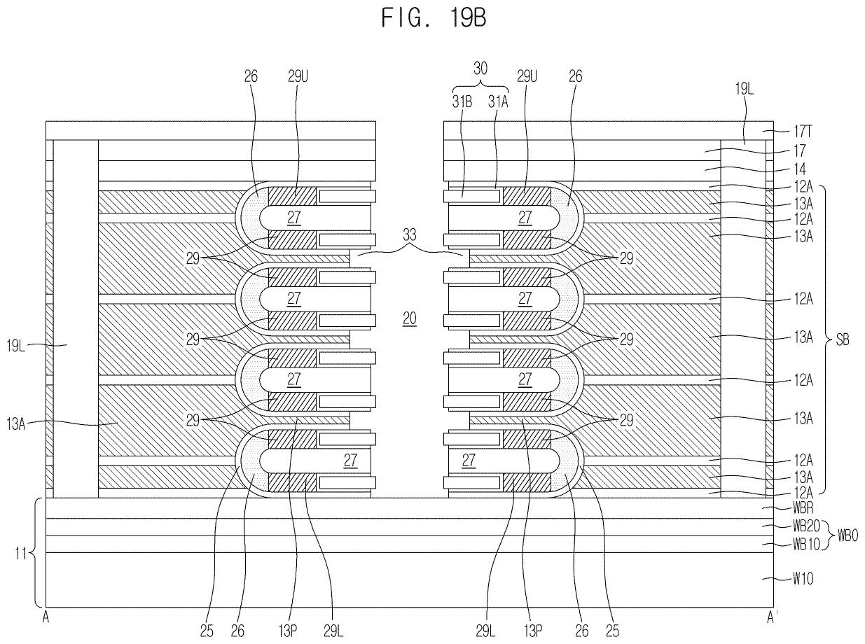

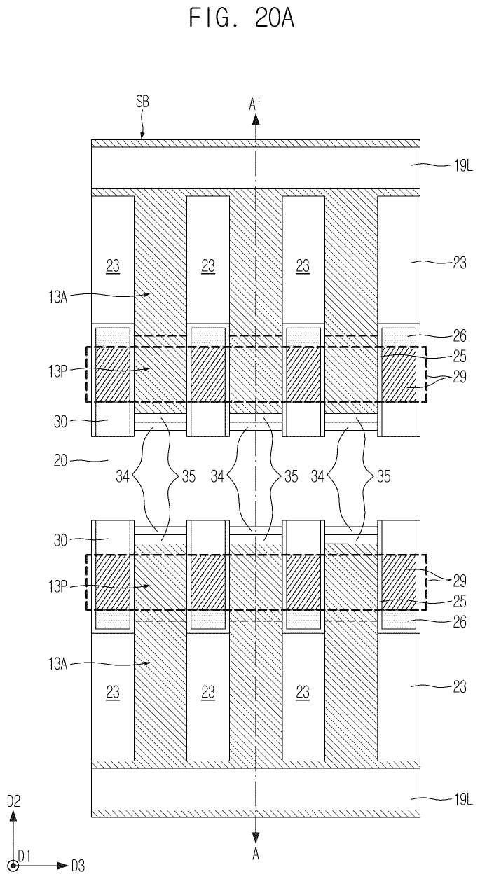

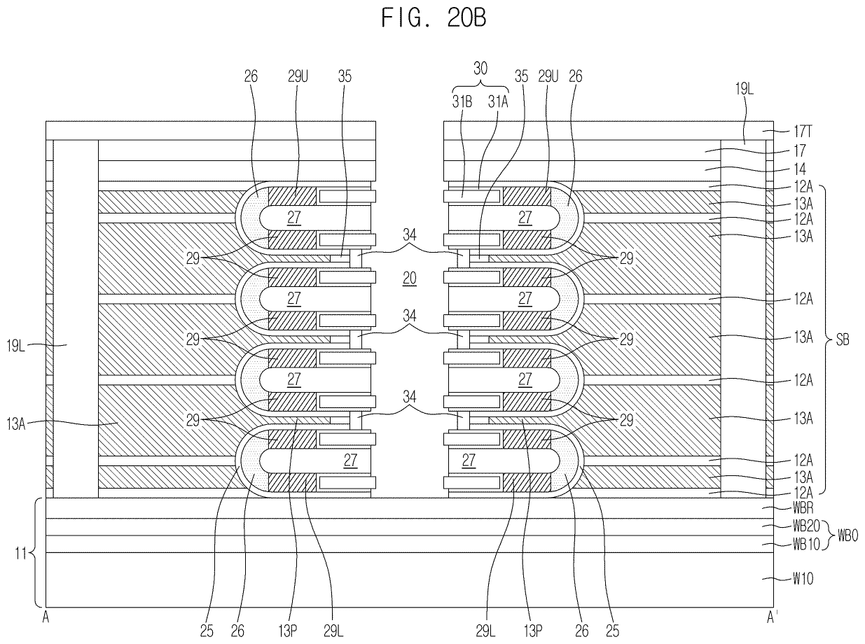

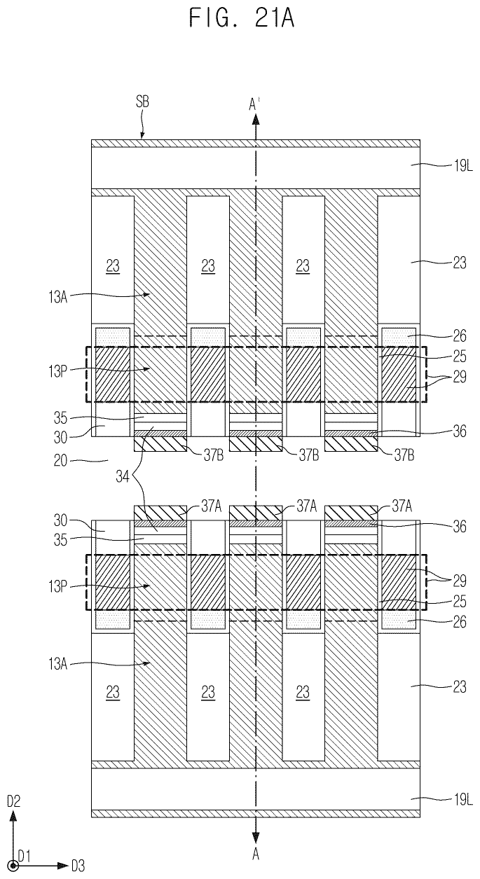

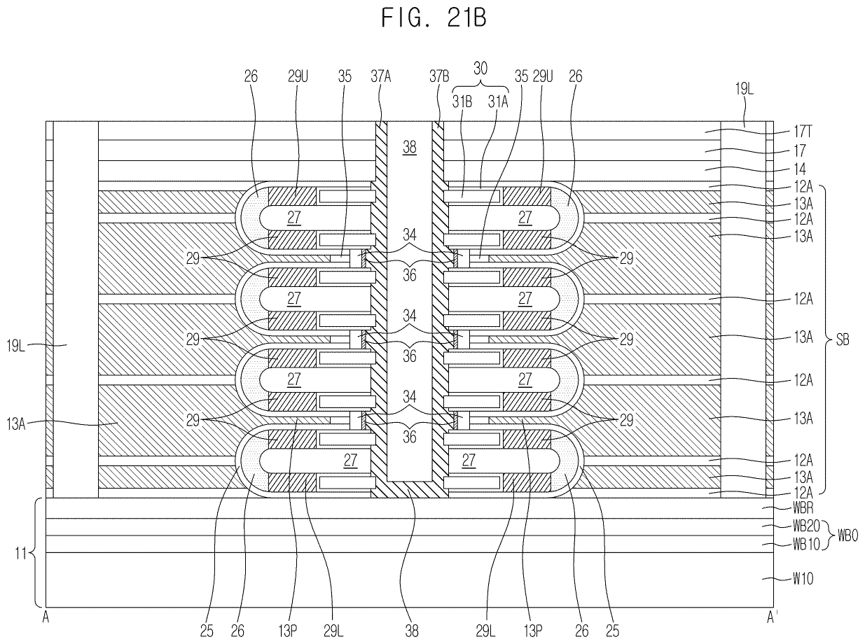

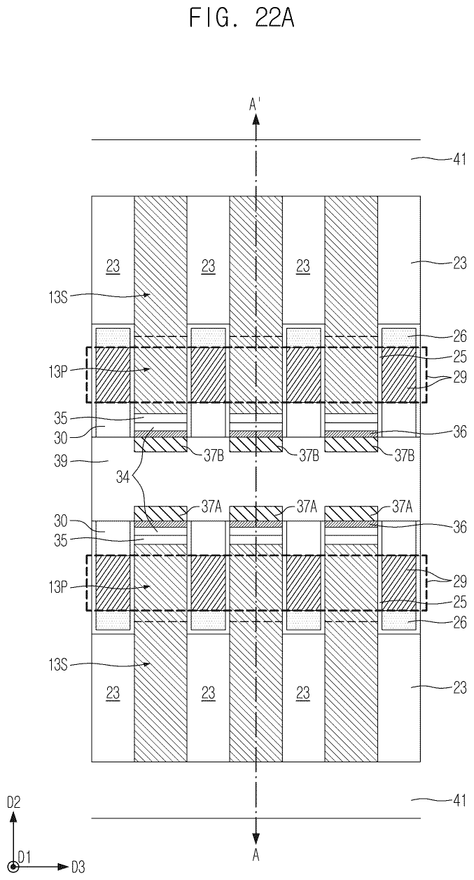

FIG. 22A is a plan view illustrating the structure at a nano sheet level to describe a method for forming second linear openings 41. FIG. 22B is a cross-sectional view illustrating the structure taken along line A-A′ illustrated in FIG. 22A.

Referring to FIGS. 22A and 22B, a vertical isolation layer 39 may be formed to fill the first linear opening 20 on the vertical conductive lines 37A and 37B. The vertical isolation layer 39 may vertically extend in the first direction D1 and horizontally extend in the third direction D3. The vertical conductive lines 37A and 37B disposed adjacent to each other in the third direction D3 may be isolated by the vertical isolation layer 39. The vertical isolation layer 39 may include a dielectric material. The vertical isolation layer 39 may include silicon oxide, silicon nitride, an air gap, or a combination thereof.

Subsequently, the second linear sacrificial layer 19L may be removed using the fourth hard mask layer 40 as a barrier. Accordingly, the second linear openings 41 may be formed.

After the second linear openings 41 are formed, the first mold layers 12A may be selectively recessed through the second linear openings 41. To selectively recess the first mold layers 12A, the difference in etch selectivity between the first mold layers 12A and the original body portions 13A may be used. The first mold layers 12A may be removed using a wet etch process or a dry etch process. For example, when the first mold layers 12A include silicon germanium layers, and the original body portions 13A include monocrystalline silicon layers, the silicon germanium layers may be etched using an etchant or etch gas having a selectivity with respect to the monocrystalline silicon layers.

Subsequently, the original body portions 13A may be recessed. To recess the original body portions 13A, the wet etch process or the dry etch process may be used. Vertical thicknesses of the original body portions 13A may be reduced, as indicated by reference numeral “13S”. Hereinafter, the original body portions having the reduced vertical thicknesses are referred to as “recessed body portions 13S”.

An inter-body recess 42 may be formed between the recessed body portions 13S that are vertically disposed.

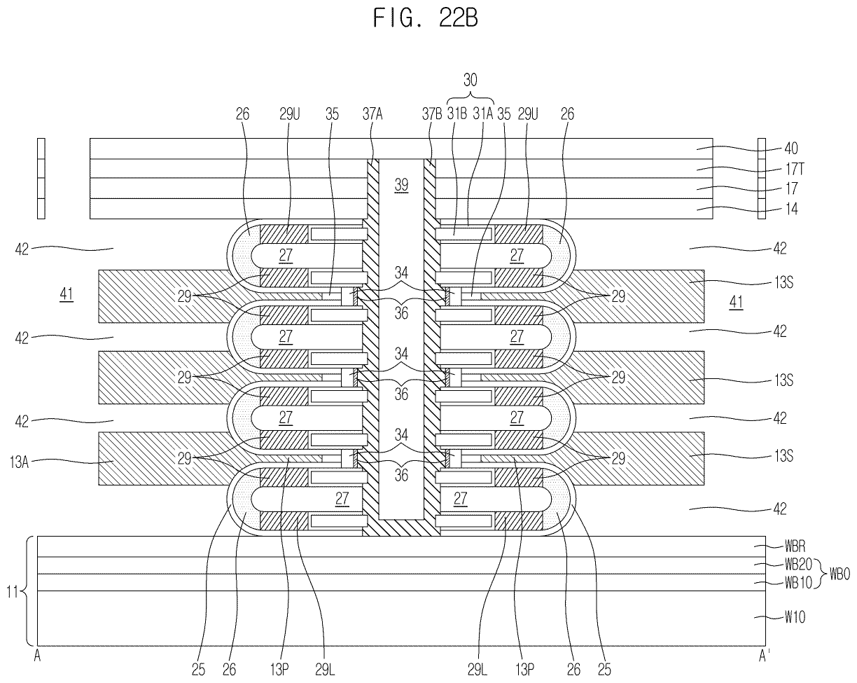

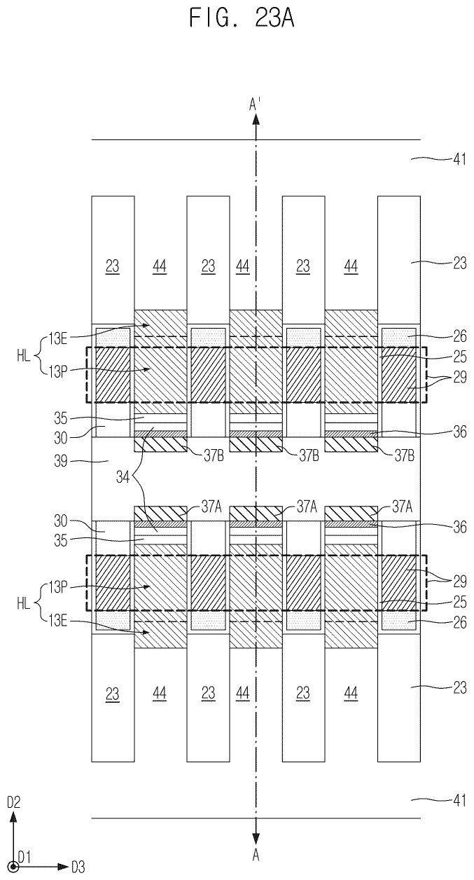

FIG. 23A is a plan view illustrating the structure at the narrow sheet level to describe a method for forming nano sheets HL. FIG. 23B is a cross-sectional view illustrating the structure taken along line A-A′ illustrated in FIG. 23A.

Referring to FIGS. 23A and 23B, third inter-cell dielectric layers 43 may be formed to fill the inter-body recesses 42. The third inter-cell dielectric layers 43 may each include silicon oxide.

After the third inter-cell dielectric layers 43 are formed, storage openings 44 may be formed by horizontal recessing of the recessed body portions 13S. The storage openings 44 may be referred to as “data storage element openings”. The nano sheets HL may be formed by the recessing of the recessed body portions 13S. Each of the nano sheets HL may include a narrow sheet 13P and a wide sheet 13E. The wide sheet 13E of the nano sheet HL may refer to the recessed body portion 13S remaining after the recessing. An average vertical height of the wide sheet 13E of the nano sheet HL in the first direction D1 may be greater than an average vertical height of the narrow sheet 13P. A thickness of the wide sheet 13E of the nano sheet HL may gradually increase in the second direction D2. A horizontal length of the wide sheet 13E in the second direction D2 may be less than a horizontal length of the narrow sheet 13P. The wide sheet 13E of the nano sheet HL may have a fan-like shape. The wide sheet 13E may be referred to as a “fan-shaped sheet”, and the narrow sheet 13P may be referred to as a “flat plate-shaped sheet”.

To form the nano sheets HL each including the wide sheet 13E, the recessed body portions 13S may be isotropically or anisotropically etched. One side of the wide sheet 13E, i.e., the side exposed by each of the storage openings 44, may have a flat shape. The one side of the wide sheet 13E may have various shapes. For example, the one side of the wide sheet 13E may have a rounded concave shape, a rounded convex shape, an angled concave shape, or an angled convex shape.

Each of the nano sheets HL may include a first edge and a second edge. The first edge may refer to a portion coupled to the vertical conductive lines 37A and 37B, and the second edge may refer to a portion exposed by each of the storage openings 44.

Each of the storage openings 44 may be disposed between the third inter-cell dielectric layers 43.

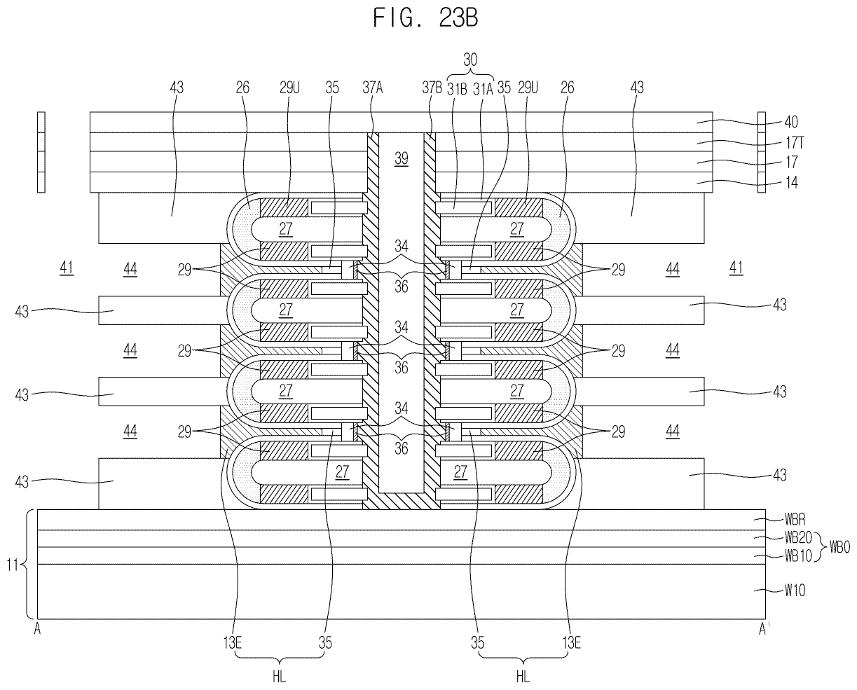

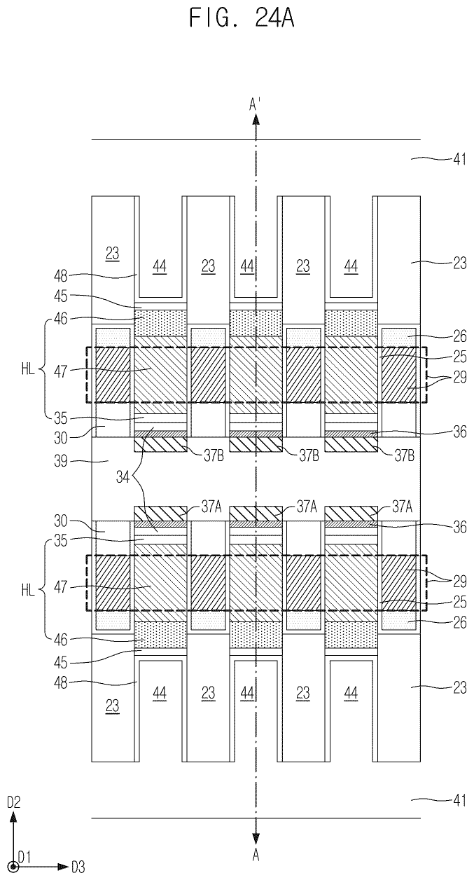

FIG. 24A is a plan view illustrating the structure at the nano sheet level to describe a method for forming second contact nodes 45 and first electrodes 48. FIG. 24B is a cross-sectional view illustrating the structure taken along line A-A′ illustrated in FIG. 24A.

Referring to FIGS. 24A and 24B, a pre-cleaning process may be performed on one side of the nano sheets HL, that is, the surfaces of the wide sheets 13E.

The second contact nodes 45 may be formed on the wide sheets 13E of the nano sheets HL. Forming the second contact nodes 45 may include conformally depositing a conductive material on the storage openings 44 and performing an etch-back process on the conductive material. The second contact nodes 45 may each include a semiconductor material. The second contact nodes 45 may each include doped polysilicon, and the doped polysilicon may include N-type dopants. Each of the second contact nodes 45 may be disposed between the third inter-cell dielectric layers 43 that are vertically stacked.

In some embodiments, forming the second contact nodes 45 may include selective epitaxial growth (SEG). For example, a semiconductor material may be grown from the side surfaces of the wide sheets 13E through the selective epitaxial growth (SEG). The second contact nodes 45 may each include SEG Si. Because the wide sheets 13E each include monocrystalline silicon, a silicon layer may be epitaxially grown along crystal surfaces of the side surfaces of the wide sheets 13E. The second contact nodes 45 may each include a dopant. When the silicon layer is grown using the selective epitaxial growth (SEG), dopants may be doped in situ. Accordingly, the second contact nodes 45 may each be a doped epitaxial layer. The second contact nodes 45 may each include an N-type dopant as the dopant. The N-type dopant may include phosphorus, arsenic, antimony, or a combination thereof. The second contact nodes 45 may include a phosphorus-doped silicon epitaxial layer formed by the selective epitaxial growth (SEG), i.e., a doped SEG SiP. In some embodiments, the first contact nodes 34 may also be formed by the selective epitaxial growth (SEG).

One side of each of the second contact nodes 45 may have various shapes. For example, one side of each of the second contact nodes 45 may have a rounded concave shape, a rounded convex shape, an angled concave shape, or an angled convex shape.

Second doped regions 46 may be formed in the wide sheets 13E of the nano sheets HL. A heat treatment process may be performed to form the second doped regions 46, and thus, dopants may be diffused from the second contact nodes 45. In another method for forming the second doped regions 46, a gas phase doping method may be applied.

Each of the nano sheets HL may include the first doped region 35, the second doped region 46, and a channel 47. The channel 47 may be defined between the first doped region 35 and the second doped region 46. The first doped region 35 and the channel 47 may be formed in the narrow sheet 13P, and the second doped region 46 may be formed in the wide sheet 13E. A portion of each of the second doped regions 46 may extend into the narrow sheets 13P. One side of each of the second doped regions 46 of the nano sheets HL may be coupled to the channel 47, and the other side of each of the second doped regions 46 of the nano sheets HL may be coupled to the second contact nodes 45.

In some embodiments, an ohmic contact layer including metal silicide may be further formed after the second contact nodes 45 are formed.

Subsequently, the first electrodes 48 of a data storage element may be formed on the second contact nodes 45. The first electrodes 48 may each have a horizontally oriented cylindrical shape. The first electrodes 48 may be respectively disposed in the storage openings 44. The first electrodes 48 disposed adjacent to each other in the second direction D2 may be spaced apart from each other by the second linear openings 41. The first electrodes 48 disposed adjacent to each other in the third direction D3 may be spaced apart from each other by the first inter-cell dielectric layers 23. The first electrodes 48 disposed adjacent to each other in the first direction D1 may be spaced apart from each other by the third inter-cell dielectric layers 43. Forming the first electrodes 48 may include depositing a metal material, gap-filling a sacrificial material, and isolating the metal material in a vertical/horizontal direction. The sacrificial material may include oxide or polysilicon.

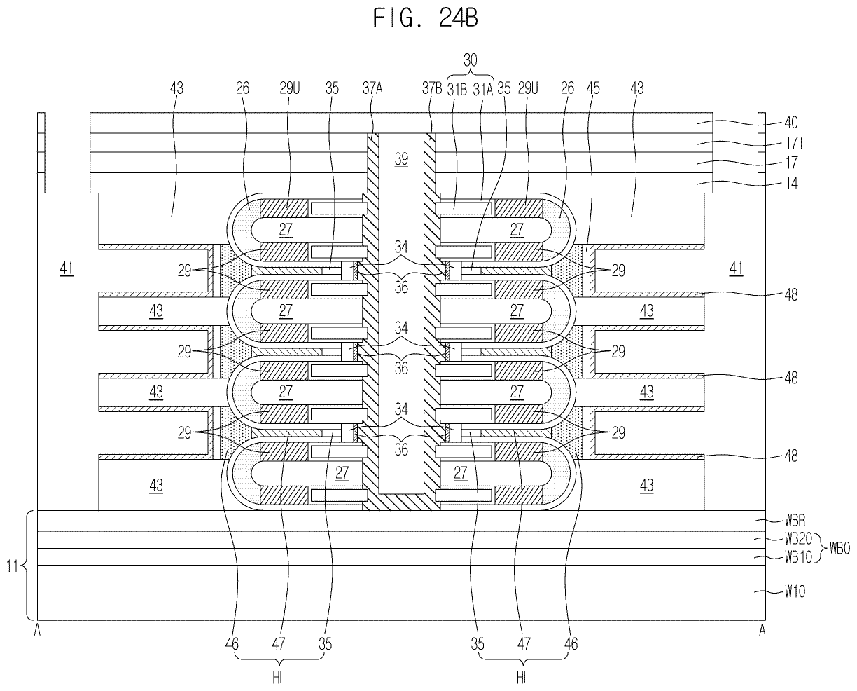

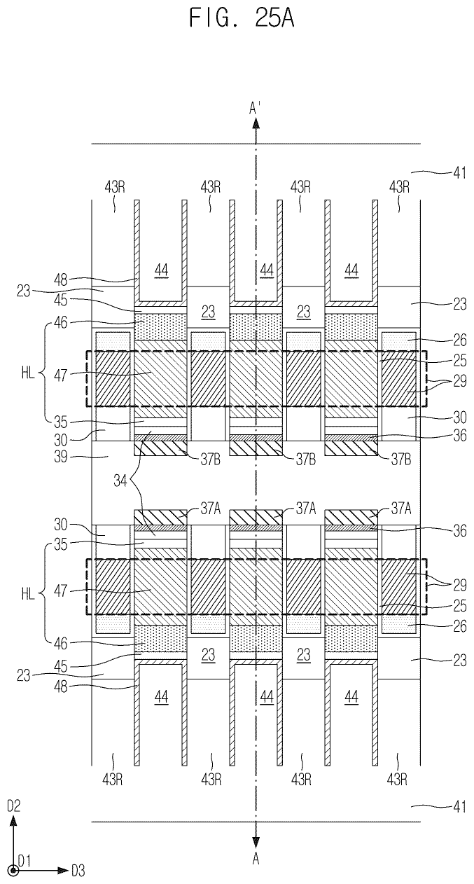

FIG. 25A is a plan view illustrating the structure at the nano sheet level to describe a method for recessing first and third inter-cell dielectric layers 23 and 43. FIG. 25B is a cross-sectional view illustrating the structure taken along line A-A′ illustrated in FIG. 25A.

Referring to FIGS. 25A and 25B, a cleaning process may be performed to horizontally recess portions of the first and third inter-cell dielectric layers 23 and 43 (refer to reference numeral “43R”). Accordingly, outer walls of the first electrodes 48 may be partially exposed. The first electrodes 48 may each have a semi-cylindrical shape. Horizontal recess depths of the first and third inter-cell dielectric layers 23 and 43 may be depths that do not expose the second contact nodes 45. When the first and third inter-cell dielectric layers 23 and 43 each include silicon oxide, the cleaning process may include a cleaning process of the oxide.

As described above, as the portions of the first and third inter-cell dielectric layers 23 and 43 are horizontally recessed, outer diameters of the first electrodes 48 may be secured. While the portions of the first and third inter-cell dielectric layers 23 and 43 are horizontally recessed, the blocking layer WBR may serve as a wet barrier, thereby preventing a bunker of the substrate W10.

As the blocking layer WBR having a selectivity with respect to the cleaning process of the first and third inter-cell dielectric layers 23 and 43 is applied, a recess target of the first and third inter-cell dielectric layers 23 and 43 may increase, which is advantageous for an increase in cell density and capacitance.

As a comparative example, the blocking layer WBR and the bonding dielectric layer WBO may be omitted, and the mold stack SB may be directly formed over the SOI substrate. However, in the comparative example, even though the SOI substrate is used, a substrate bunker may occur during the cleaning process of the first and third inter-cell dielectric layers 23 and 43.

The blocking layer WBR according to the present embodiment has resistivity with respect to the cleaning process of silicon, silicon oxide, and silicon nitride.

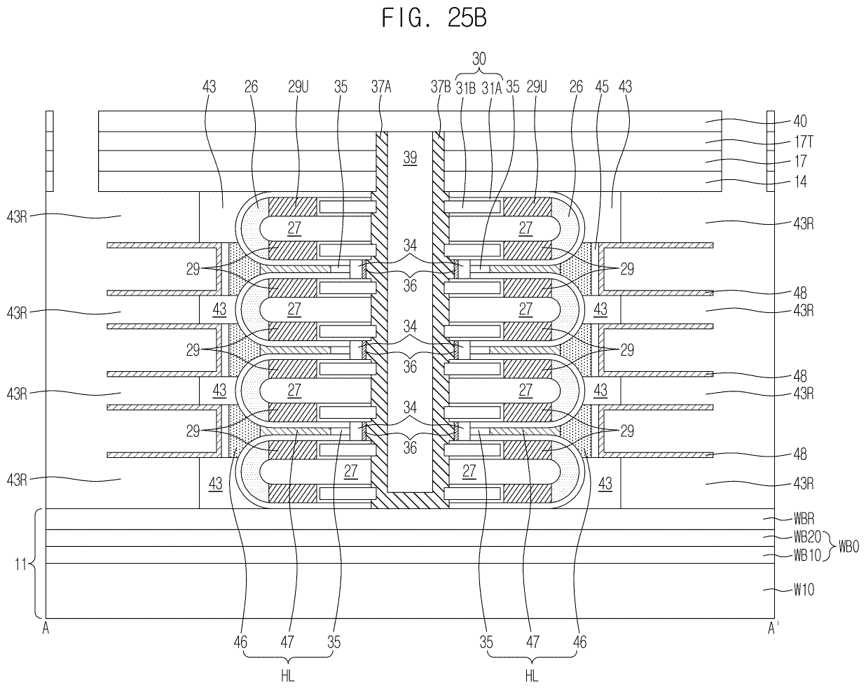

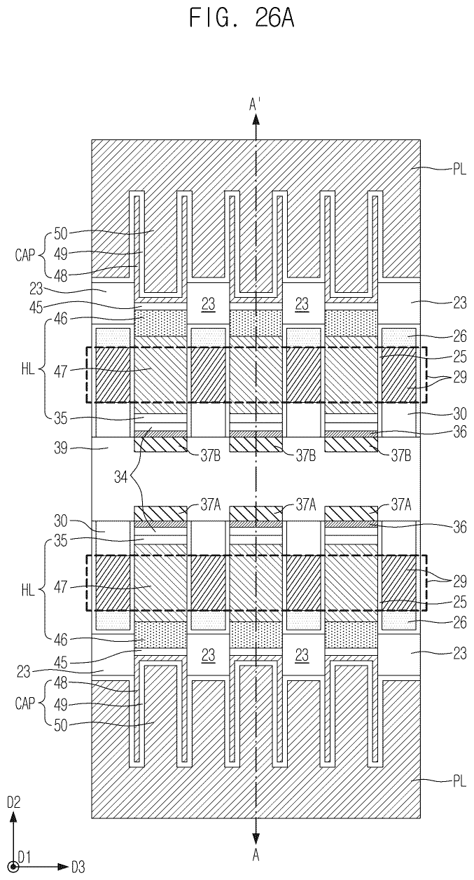

FIG. 26A is a plan view illustrating the structure at the nano sheet level to describe a method for forming second electrodes 50 of the data storage element. FIG. 26B is a cross-sectional view illustrating the structure taken along line A-A′ illustrated in FIG. 26A.

Referring to FIGS. 26A and 26B, a dielectric layer 49 and the second electrode 50 may be sequentially formed on each of the first electrodes 48. The first electrode 48, the dielectric layer 49, and the second electrode 50 may be the data storage element CAP.

The first electrode 48 may include an inner space and a plurality of outer surfaces. The inner space of the first electrode 48 may include a plurality of inner surfaces. The outer surfaces of the first electrode 48 may include a vertical outer surface and a plurality of horizontal outer surfaces. The vertical outer surface of the first electrode 48 may vertically extend in the first direction D1. The horizontal outer surfaces of the first electrode 48 may horizontally extend in the second direction D2 or the third direction D3. The inner space of the first electrode 48 may be a three-dimensional space. The dielectric layer 49 may conformally cover the inner surfaces and horizontal outer surfaces of the first electrode 48. The second electrode 50 may be disposed on the inner space and horizontal outer surfaces of the first electrode 48 on the dielectric layer 49. Among the outer surfaces of the first electrode 48, the vertical outer surface may be electrically coupled to the nano sheet HL and the second contact node 45.

The first electrode 48 may have a semi-cylindrical shape. The semi-cylindrical shape of the first electrode 48 may include cylindrical inner surfaces and semi-cylindrical outer surfaces. The dielectric layer 49 and the second electrode 50 may be disposed on the cylindrical inner surfaces of the first electrode 48. A portion of the dielectric layer 49 and a portion of the second electrode 50 may extend to be disposed on the semi-cylindrical outer surfaces of the first electrode 48. The second electrode 50 may vertically extend in the first direction D1.

The first electrode 48 and the second electrode 50 may each include metal, noble metal, metal nitride, conductive metal oxide, conductive noble metal oxide, metal carbide, metal silicide, or a combination thereof. For example, the first electrode 48 and the second electrode 50 may each include titanium (Ti), titanium nitride (TiN), titanium silicon nitride (TiSiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, a tungsten nitride/tungsten (WN/W) stack, a titanium silicon nitride/titanium nitride (TiSiN/TiN) stack, or a combination thereof. The second electrode 50 may also include a combination of a metal-based material and a silicon-based material. For example, the second electrode 50 may be a titanium nitride/silicon germanium/tungsten nitride (TiN/SiGe/WN) stack. In the titanium nitride/silicon germanium/tungsten nitride (TiN/SiGe/WN) stack, silicon germanium may be a gap-fill material filling the inner space of the first electrode 48, and titanium nitride (TiN) may serve as the second electrode 50 of the data storage element CAP, and tungsten nitride may be a low-resistivity material.

The dielectric layer 49 may be referred to as a “capacitor dielectric layer” or a “memory layer”. The dielectric layer 49 may include silicon oxide, silicon nitride, a high-k material, a ferroelectric material, an antiferroelectric material, a perovskite material, or a combination thereof. The dielectric layer 49 may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃). The dielectric layer 49 may include a ZA (ZrO₂/Al₂O₃) stack, a ZAZ (ZrO₂/Al₂O₃/ZrO₂) stack, a ZAZA (ZrO₂/Al₂O₃/ZrO₂/Al₂O₃) stack, a ZAZAZ (ZrO₂/Al₂O₃/ZrO₂/Al₂O₃/ZrO₂) stack, a HA (HfO₂/Al₂O₃) stack, a HAH (HfO₂/Al₂O₃/HfO₂) stack, a HAHA (HfO₂/Al₂O₃/HfO₂/Al₂O₃) stack, a HAHAH (HfO₂/Al₂O₃/HfO₂/Al₂O₃/HfO₂) stack, a HZAZH (HfO₂/ZrO₂/Al₂O₃/ZrO₂/HfO₂) stack, a ZHZAZHZ (ZrO₂/HfO₂/ZrO₂/Al₂O₃/ZrO₂/HfO₂/ZrO₂) stack, a HZHZ (HfO₂/ZrO₂/HfO₂/ZrO₂) stack, or AHZAZHA (Al₂O₃/HfO₂/ZrO₂/Al₂O₃/ZrO₂/HfO₂/Al₂O₃) stack.

In some embodiments, an interface control layer may be further formed between the first electrode 48 and the dielectric layer 49 to alleviate leakage current. The interface control layer may include titanium oxide (TiO₂), tantalum oxide (Ta₂O₅), niobium oxide (Nb₂O₅), niobium nitride (NbN), or a combination thereof. The interface control layer may also be formed between the second electrode 50 and the dielectric layer 49.

The dielectric layer 49 may be in direct contact with the blocking layer WBR. Because the blocking layer WBR is disposed between the dielectric layer 49 and the substrate W10, leakage between the dielectric layer 49 and the substrate W10 may be prevented.

A semiconductor device according to a series of processes described above may include the substrate W10, the bonding dielectric layer WBO over the substrate W10, the blocking layer WBR on the bonding dielectric layer WBO, and the memory cell array MCA including a plurality of memory cells vertically stacked over the blocking layer WBR. As described above, the memory cell array MCA may be formed on the lower structure 11 including the blocking layer WBR. The memory cell array MCA may include the nano sheets HL, the horizontal conductive lines 29, the vertical conductive lines 37A and 37B, and the data storage elements CAP. The lower structure 11 may include the substrate W10, the bonding dielectric layer WBO, and the blocking layer WBR.

As described above, because the blocking layer WBR is formed between the substrate W10 and the memory cell array MCA, wet resistivity of the substrate W10 may be enhanced. The substrate bunker may be prevented during the recess processes for securing the outer diameter of the first electrode 48 of the data storage element CAP. As the outer diameter of the first electrode 48 is secured, an increase in capacitance and the cell density may be improved. Because the substrate bunker is prevented, leakage between the dielectric layer 49 of the data storage element CAP and the substrate W10 may be prevented, and wafer stability during a subsequent packaging process may be enhanced.

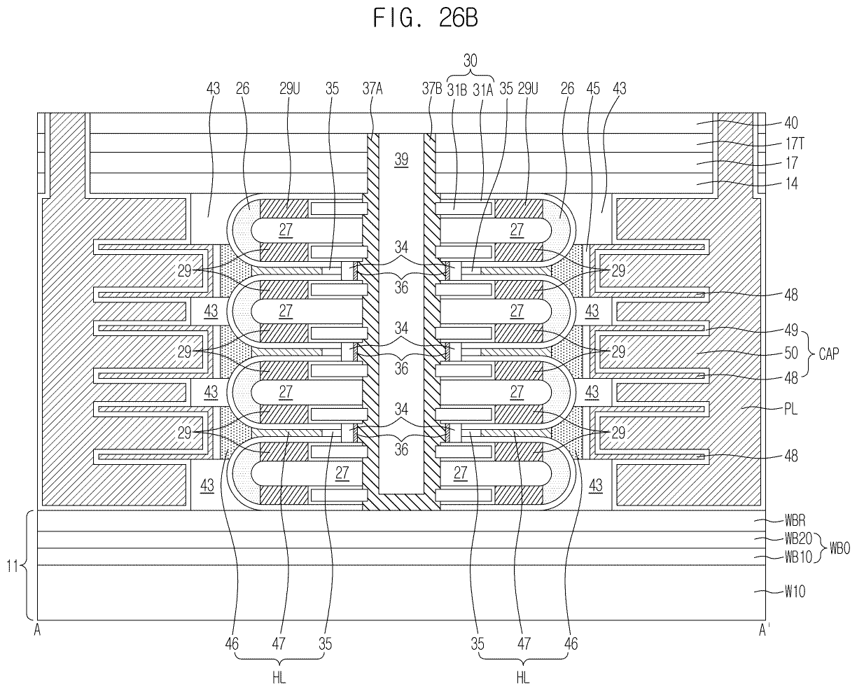

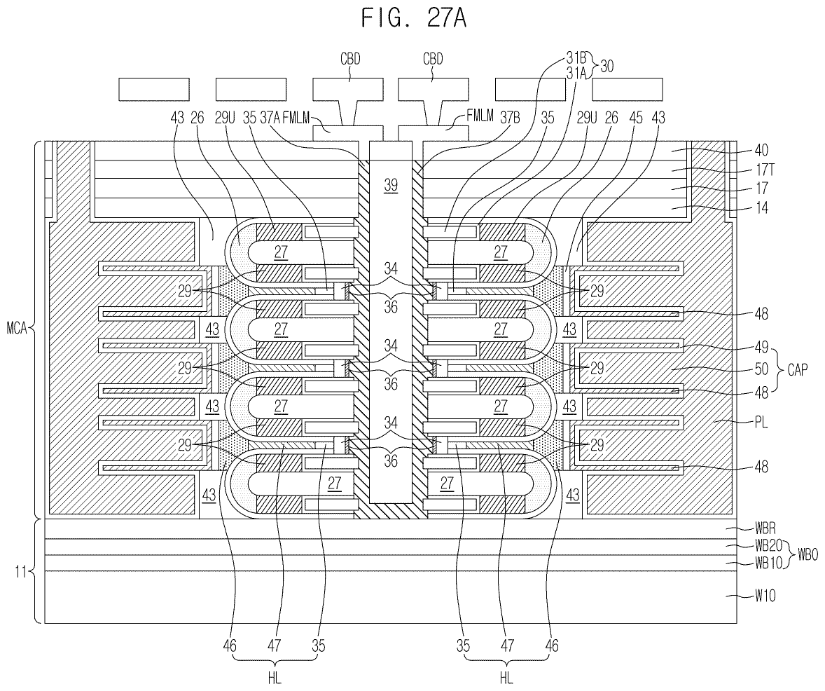

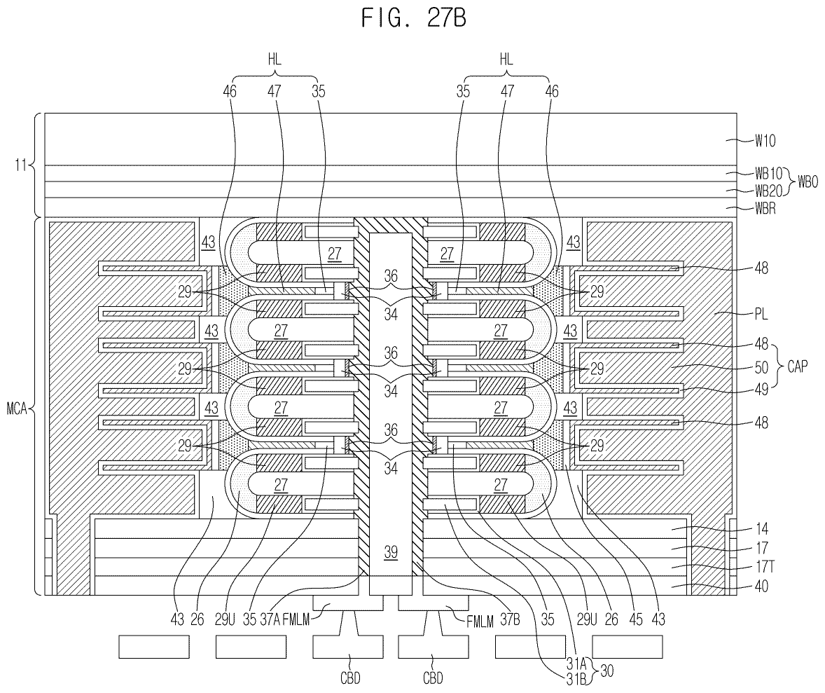

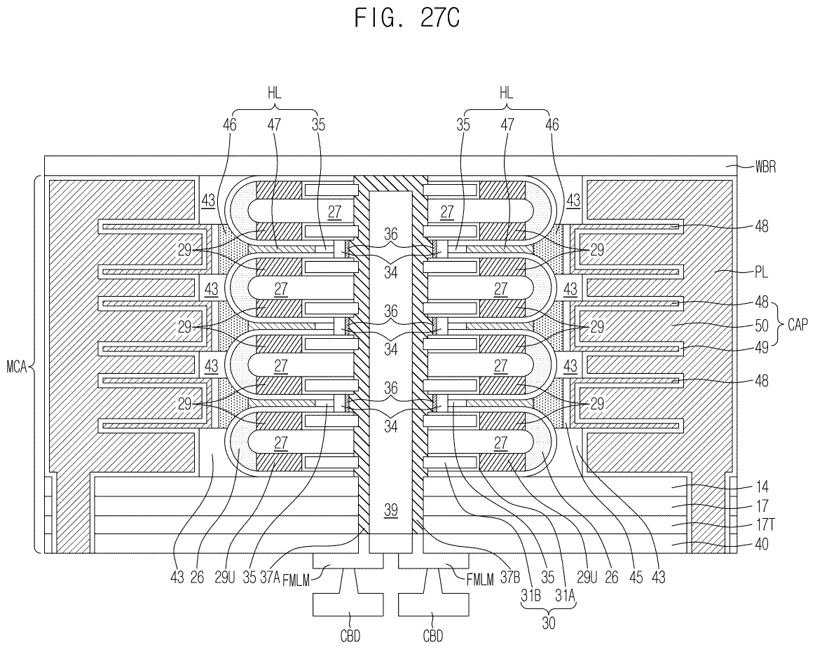

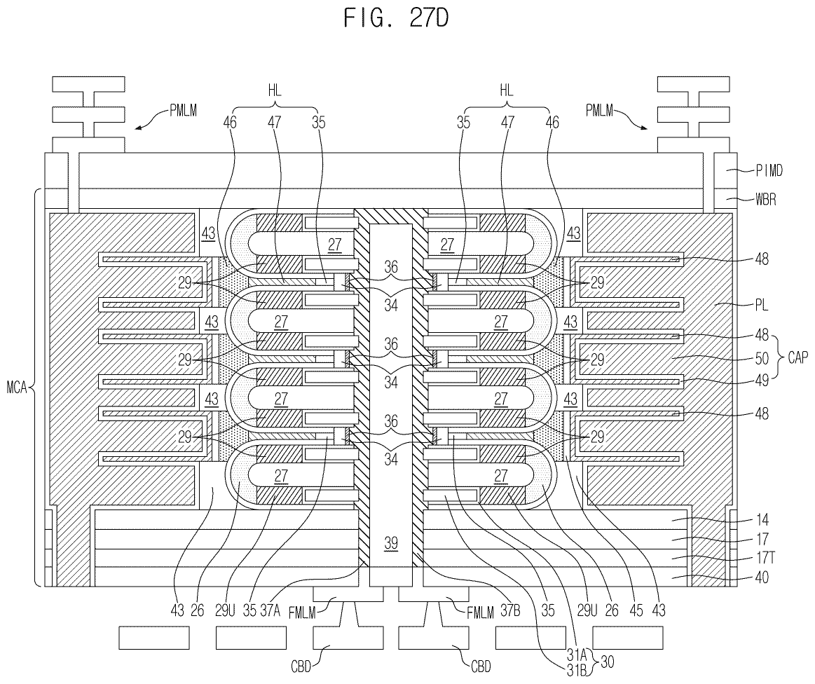

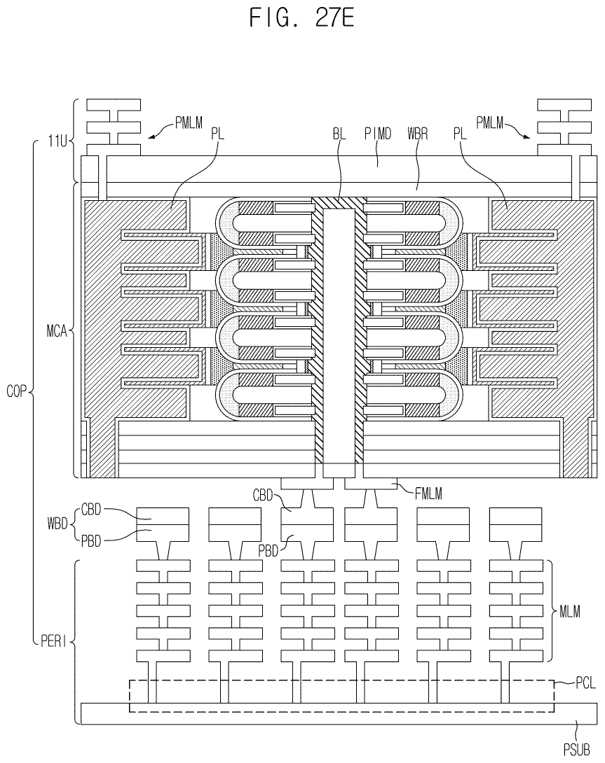

FIGS. 27A to 27E are various views illustrating the memory cell array MCA and a bonding processor of a peripheral circuit portion PERI in accordance with an embodiment of the present disclosure.

Referring to FIG. 27A, front interconnection structure FMLM coupled to the first and second vertical conductive lines 37A and 37B of the memory cell array MCA may be formed. The front interconnection structure FMLM may include metal or a metal-based material. Deposition and etch processes of a metal material may be performed to form the front interconnection structure FMLM. The substrate W10 on which the memory cell array MCA is formed may be a first substrate.

Subsequently, first bonding pads CBD may be formed on the front interconnection structure FMLM. The first bonding pads CBD may include metal or a metal-based material. Deposition and etch processes of a metal material may be performed to form the first bonding pads CBD.

Referring to FIG. 27B, the resultant substrate W10 of FIG. 27A may be flipped so that the first bonding pads CBD are disposed at the lowermost level. The process of flipping the substrate W10 may be referred to as a “wafer flip process” or a “substrate flip process”. The substrate W10 may be disposed at the uppermost level, and the memory cell array MCA may be disposed between the substrate W10 and the first bonding pads CBD. The blocking layer WBR may be disposed between the substrate W10 and the memory cell array MCA. The first and second bonding dielectric layers WB10 and WB20 may be disposed between the blocking layer WBR and the substrate W10.

Referring to FIG. 27C, the substrate W10 and the first and second bonding dielectric layers WB10 and WB20 of FIG. 27B may be removed by a removal process such as a planarization process and a wet cleaning process. During the removal of the substrate W10 and the first and second bonding dielectric layers WB10 and WB20, the blocking layer WBR may serve to protect the memory cell array MCA. In some embodiments, the blocking layer WBR may be removed after the removal of the first and second bonding dielectric layers WB10 and WB20.

Referring to FIG. 27D, a post interlayer dielectric layer PIMD may be formed on the remaining blocking layer WBR. The post interlayer dielectric layer PIMD may include a dielectric material such as silicon oxide or silicon carbon oxide.

Post interconnection structures PMLM that penetrate the post interlayer dielectric layer PIMD and are coupled to the common plate PL of the data storage element CAP may be formed. The post interconnection structure PMLM may include metal or a metal-based material. The post interconnection structure PMLM may have a multilayer structure. A via etch process and deposition and etch processes of a metal material may be performed to form the post interconnection structure PMLM.

Referring to FIG. 27E, the peripheral circuit portion PERI may be prepared. The peripheral circuit portion PERI may include a peripheral circuit substrate PSUB, a control circuit PCL, a multilayer level interconnection MLM, and second bonding pads PBD. The control circuit PCL may include a sense amplifier. The peripheral circuit substrate PSUB may be a second substrate.

Subsequently, the memory cell array MCA and the peripheral circuit portion PERI may be bonded through wafer bonding. Descriptions of the components of the memory cell array MCA are provided above with reference to FIGS. 27A to 27C.

The first bonding pads CBD and the second bonding pads PBD may be bonded through wafer bonding. The memory cell array MCA and the peripheral circuit portion PERI may be electrically coupled to each other through a bonding structure WBD. The bonding structure WBD may include the first bonding pads CBD and the second bonding pads PBD.

In some embodiments, the method for bonding the memory cell array MCA and the peripheral circuit portion PERI may include pad bonding, hybrid bonding, oxide-to-oxide bonding, metal-to-metal bonding, or a combination thereof. The hybrid bonding may refer to a combination of the pad bonding and the oxide-to-oxide bonding.

A semiconductor device COP may include a stack of the memory cell array MCA and the peripheral circuit portion PERI. The memory cell array MCA may be disposed at a higher level than the peripheral circuit portion PERI. That is, the peripheral circuit portion PERI and the memory cell array MCA may have a cell over peripheral (COP) structure. The semiconductor device COP may further include an upper structure 11U disposed above the memory cell array MCA. The upper structure 11U may include the post interlayer dielectric layer PIMD and the post interconnection structure PMLM.

As described above, the semiconductor device COP may include the memory cell array MCA including a plurality of memory cells that are vertically stacked, the peripheral circuit portion PERI for controlling the memory cells of the memory cell array MCA, the bonding structure WBD between the memory cell array MCA and the peripheral circuit portion PERI, and the blocking layer WBR that is spaced apart from the bonding structure WBD and covers a portion of the memory cell array MCA.

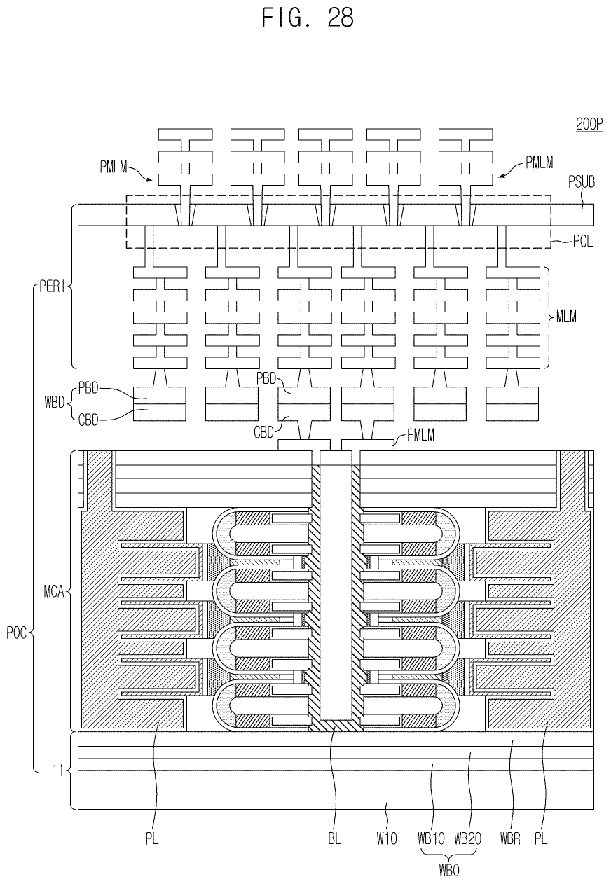

FIG. 28 is a schematic cross-sectional view illustrating a semiconductor device 200P in accordance with an embodiment of the present disclosure.

Referring to FIG. 28, the semiconductor device 200P may include a stack of a peripheral circuit portion PERI and a memory cell array MCA. The memory cell array MCA may include a three-dimensional array of memory cells as referenced in the above-described embodiment. The memory cell array MCA may include the same components as described with reference to FIG. 27A.

In the semiconductor device 200P, the peripheral circuit portion PERI may be electrically coupled to the memory cell array MCA through a bonding structure WBD. The bonding structure WBD may include first bonding pads CBD and second bonding pads PBD.

The memory cell array MCA and the first bonding pads CBD may be coupled to a front interconnection structure FMLM. The front interconnection structure FMLM may be coupled to a portion of the memory cell array MCA. The front interconnection structure FMLM may be disposed at a higher level than the memory cell array MCA. The peripheral circuit portion PERI may be disposed at a higher level than the front interconnection structure FMLM. After a peripheral circuit substrate PSUB on which peripheral circuits and multilayer level interconnections are formed is flipped, the peripheral circuits and the multilayer level interconnections may be intercoupled to each other through the first and second bonding pads CBD and PBD. A post interconnection structure PMLM may be coupled to a control circuit PCL through a nano-silicon via penetrating the peripheral circuit substrate PSUB. Before the post interconnection structure PMLM is formed, a rear surface of the peripheral circuit substrate PSUB may be back-ground.

The memory cell array MCA may be disposed at a higher level than a lower structure 11. The memory cell array MCA may be disposed at a lower level than the peripheral circuit portion PERI. That is, the peripheral circuit portion PERI and the memory cell array MCA of the semiconductor device 200P may have a peripheral over cell (POC) structure.

As described above, the semiconductor device 200P may include a substrate W10, a bonding dielectric layer WBO on the substrate W10, a blocking layer WBR on the bonding dielectric layer WBO, the memory cell array MCA including a plurality of memory cells vertically stacked over the blocking layer WBR, the peripheral circuit portion PERI for controlling the memory cells of the memory cell array MCA, and the bonding structure WBD between the memory cell array MCA and the peripheral circuit portion PERI.

FIGS. 29A and 29B are various views illustrating a stack assembly in accordance with an embodiment of the present disclosure.

Referring to FIG. 29A, a stack assembly 300 may include an assembly of semiconductor dies. For example, the stack assembly 300 may include a first semiconductor die BSD and a plurality of second semiconductor dies 301. The first semiconductor die BSD may include logic circuits. Each of the second semiconductor dies 301 may include memory cell arrays according to the embodiments described above. Each of the second semiconductor dies 301 may include a structure in which a memory cell array and a peripheral circuit portion are stacked, for example, a COP structure or a POC structure. The logic circuits of the first semiconductor die BSD and the peripheral circuit portions of the second semiconductor dies 301 may be different from each other. The second semiconductor dies 301 may be at a chip level or a wafer level.

The second semiconductor dies 301 may be electrically coupled to one another through a plurality of through silicon vias TSV and a plurality of bonding interfaces CBS. The first semiconductor die BSD and the second semiconductor die 301 at the lowest level may be electrically coupled to each other through the bonding interface CBS. The second semiconductor dies 301 may be referred to as “core dies”, “semiconductor chips”, or “memory chips”.

The bonding interface CBS may include a micro-bump, pad bonding, hybrid bonding, oxide-to-oxide bonding, metal-to-metal bonding, or a combination thereof.

In some embodiments, the second semiconductor dies 301 may be wafer flipped and back-ground to form the bonding interfaces CBS.

Referring to FIG. 29B, a stack assembly 400 may include an assembly of semiconductor dies. For example, the stack assembly 400 may include a first semiconductor die BSD, a plurality of second semiconductor dies 401, and a plurality of third semiconductor dies 402. The first semiconductor die BSD may include logic circuits. Each of the second semiconductor dies 401 and each of the third semiconductor dies 402 may include memory cell arrays according to the embodiments described above. The second semiconductor dies 401 and the third semiconductor dies 402 may have different structures.

Each of the second semiconductor dies 401 may include a COP structure in which a memory cell array is stacked over a peripheral circuit portion Each of the third semiconductor dies 402 may include a POC structure in which a peripheral circuit portion is stacked over a memory cell array.

In some embodiments, each of the second semiconductor dies 401 may include a POC structure in which a peripheral circuit portion is stacked over a memory cell array. Each of the third semiconductor dies 402 may include a COP structure in which a memory cell array is stacked over a peripheral circuit portion.

The logic circuits of the first semiconductor die BSD may be different from the peripheral circuit portions of the second and third semiconductor dies 401 and 402. The second and third semiconductor dies 401 and 402 may be at a chip level or a wafer level.

The second and third semiconductor dies 401 and 402 may be electrically coupled to each other through a plurality of through silicon vias TSV and bonding interfaces CBS. The first semiconductor die BSD and the second semiconductor die 401 at the lowest level may be electrically coupled to each other through the bonding interface CBS. The second and third semiconductor dies 401 and 402 may be referred to as “core dies”, “semiconductor chips”, or “memory chips”.

The bonding interface CBS may include a micro-bump, pad bonding, hybrid bonding, oxide-to-oxide bonding, metal-to-metal bonding, or a combination thereof.

In some embodiments, wafer flip and back grinding processes may be performed to form the bonding interfaces CBS. For example, the second semiconductor dies 401 and/or the third semiconductor dies 402 may be wafer flipped and back-ground.

The stack assemblies 300 and 400 illustrated in FIGS. 29A and 29B may be high bandwidth memories.

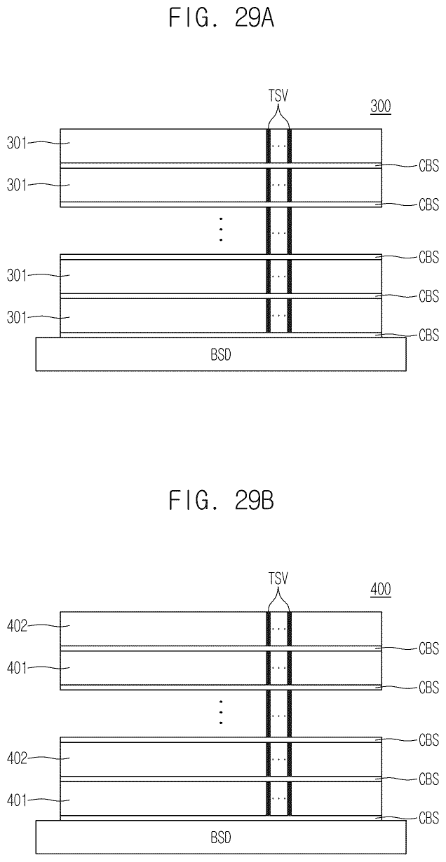

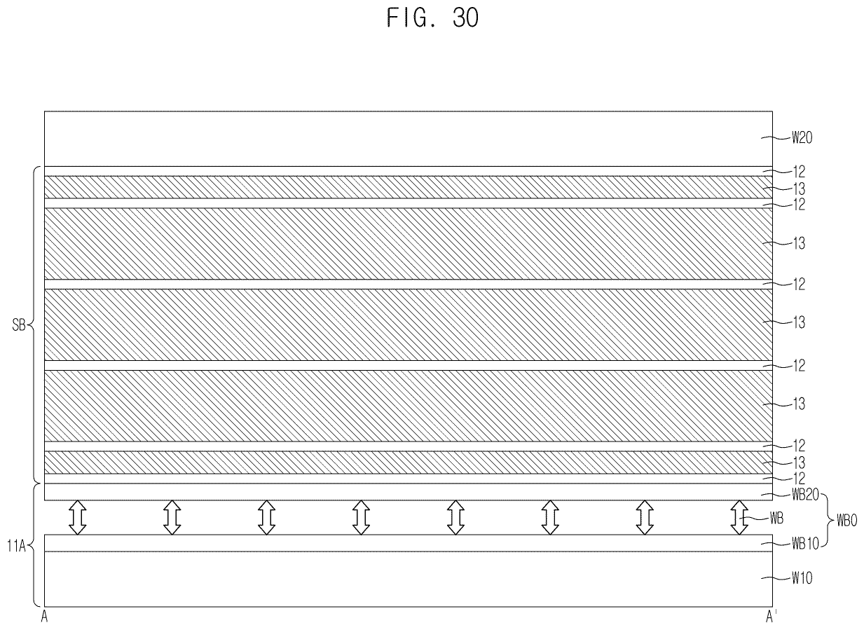

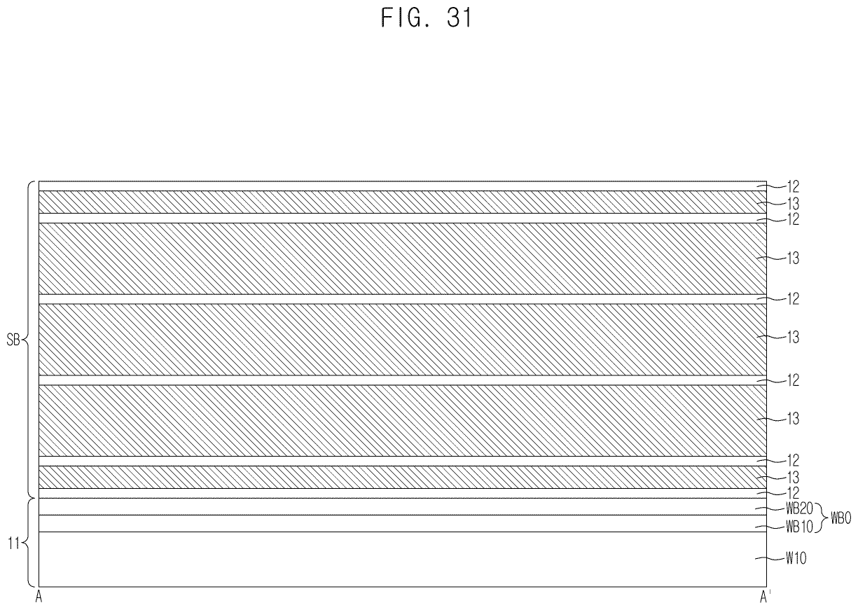

FIGS. 30 and 31 illustrate various views of a mold stack structure formed utilizing a method for fabricating the mold stack structure in accordance with an embodiment of the present disclosure.

Referring to FIG. 30, a first bonding dielectric layer WB10 may be formed on a substrate W10. The substrate W10 may be a material suitable for semiconductor processing. The substrate W10 may include at least one of a conductive material, a dielectric material, and a semiconductive material. The substrate W10 may include silicon, monocrystalline silicon, polysilicon, amorphous silicon, silicon germanium, monocrystalline silicon germanium, polycrystalline silicon germanium, carbon-doped silicon, a combination thereof, or a multilayer thereof. The substrate W10 may also include another semiconductor material such as germanium. The substrate W10 may also include a III-V group semiconductor substrate, for example, a compound semiconductor substrate such as GaAs. The first bonding dielectric layer WB10 may include an oxide-based material such as silicon oxide.

A mold stack SB may be formed on a sacrificial substrate W20. The mold stack SB may include an alternating stack of first mold layers 12 and second mold layers 13. The first mold layers 12 may be alternately stacked with the second mold layers 13. The first mold layers 12 and the second mold layers 13 may be epitaxially grown multiple times, to form the mold stack SB. In the mold stack SB, alternating layers of the first mold layer 12 and the second mold layer 13 may be repeatedly grown to form multi-level tiers such as tier 1, tier 2, and tier 3. Each of the tiers may include a two-layer structure of the first mold layer 12 and the second mold layer 13. The first mold layer 12 may be disposed at the top of the mold stack SB.

The first mold layers 12 and the second mold layers 13 may be different semiconductor materials. The first mold layers 12 may include silicon germanium or monocrystalline silicon germanium. The second mold layers 13 may include monocrystalline silicon. The first mold layers 12 and the second mold layers 13 may be formed by an epitaxial growth process. The lowermost first mold layer 12 may serve as a seed layer during the epitaxial growth process. The first mold layers 12 may be thinner than the second mold layers 13. The first mold layers 12 may include first epitaxially grown layers, and the second mold layers 13 may include second epitaxially grown layers.

In an embodiment, a plurality of monocrystalline silicon germanium layers may be alternately stacked with a plurality of monocrystalline silicon layers in the mold stack SB. For example, the first mold layers 12 may be the monocrystalline silicon germanium layers, and the second mold layers 13 may be the monocrystalline silicon layers. A stack of a monocrystalline silicon germanium layer and a monocrystalline silicon layer (a SiGe/Si stack) may be stacked multiple times. The first mold layers 12 may be referred to as “sacrificial layers”, and the second mold layers 13 may be referred to as “nano sheet target layers” or “recess target layers”.

The mold stack SB may be referred to as a “vertical stack”. The mold stack SB may be formed by alternately stacking a plurality of sacrificial layers and a plurality of nano sheet target layers. The sacrificial layers may be monocrystalline silicon germanium layers, and the nano sheet target layers may be monocrystalline silicon layers.

A thickness ratio of the first mold layers 12 and the second mold layers 13 in the mold stack SB may be variously modified. For example, the thickness of the first mold layers 12 may be approximately 5 to 20 nm, and the thickness of the second mold layers 13 may be approximately 50 to 80 nm. The quantity of the first mold layers 12 and the quantity of the second mold layers 13 in the mold stack SB may be variously modified. In some embodiments, a triple stack including the first mold layer 12, the second mold layer 13, and the first mold layer 12 may be defined at the lowermost and/or uppermost portions of the mold stack SB. The second mold layer 13 of the triple stack may have a thickness less than the second mold layer 13 of the mold stack SB.

A second bonding dielectric layer WB20 may be formed below the mold stack SB. The second bonding dielectric layer WB20 may include an oxide-based material such as silicon oxide.

Subsequently, the sacrificial substrate W20 may be flipped so that the second bonding dielectric layer WB20 is disposed at the lowermost level. Accordingly, the first bonding dielectric layer WB10, the second bonding dielectric layer WB20, the mold stack SB, and the sacrificial substrate W20 may be sequentially stacked on the substrate W10. The process of flipping the sacrificial substrate W20 on which the mold stack SB is formed may be referred to as a “wafer flip” or a “substrate flip”.

Subsequently, a wafer bonding process WFB may be performed to bond the first bonding dielectric layer WB10 and the second bonding dielectric layer WB20.

After the wafer bonding process WFB is performed, a bonding dielectric layer WBO may be formed, as illustrated in FIG. 31. The first bonding dielectric layer WB10 and the second bonding dielectric layer WB20 may be bonded by oxide-to-oxide bonding. The bonding dielectric layer WBO may include a stack of the first bonding dielectric layer WB10 and the second bonding dielectric layer WB20.

After the wafer bonding process WFB is performed, a mold stack structure including a lower structure 11, the mold stack SB, and the sacrificial substrate W20 may be formed. The lower structure 11 may include a stack of the substrate W10, the first bonding dielectric layer WB10, and the second bonding dielectric layer WB20. The mold stack SB may be disposed over the lower structure 11, and the sacrificial substrate W20 may be disposed over the mold stack SB.

Subsequently, the sacrificial substrate W20 may be removed.

Subsequently, a series of processes described with reference to FIGS. 8A to 26B may be performed to form a memory cell array in the mold stack SB.

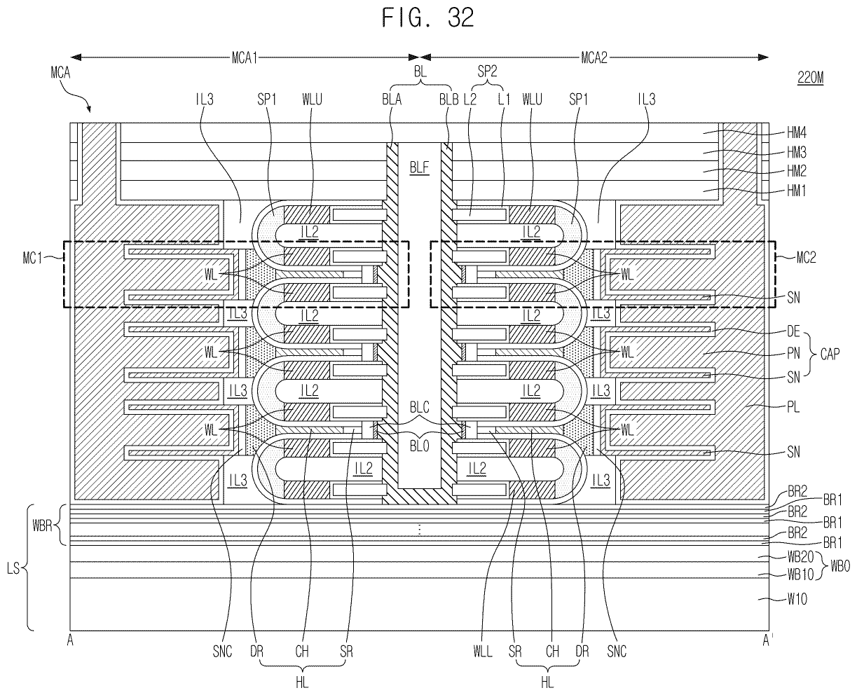

FIG. 32 is a schematic view illustrating a semiconductor device 200M in accordance with an embodiment of the present disclosure.

The semiconductor device 200M illustrated in FIG. 32 may be similar to the semiconductor device 200 illustrated in FIGS. 3 to 4B. Hereinafter, detailed descriptions of overlapping components are provided above with reference to FIGS. 3 to 4B.

Referring to FIGS. 3, 4A, 4B and 32, the semiconductor device 200M may include a memory cell array MCA and a lower structure LS below the memory cell array MCA. The memory cell array MCA may include a three-dimensional array of memory cells MC1 and MC2. The memory cell array MCA may include a first sub-cell array MCA1 and a second sub-cell array MCA2. The memory cell array MCA may include a plurality of memory cells MC1 and MC2 vertically stacked in a first direction D1.

The lower structure LS may include a Silicon On Insulator (SOI) structure. For example, the lower structure LS may include a stack of a substrate W10, a bonding dielectric layer WBO and a blocking layer WBR. The bonding dielectric layer WBO may have a double structure of a first bonding dielectric layer WB10 and a second bonding dielectric layer WB20. The bonding dielectric layer WBO may be formed between the substrate W10 and the blocking layer WBR. The substrate W10 may be a silicon-containing material, and the bonding dielectric layer WBO and the blocking layer WBR may be dielectric materials. The substrate W10 may include a monocrystalline silicon layer. The bonding dielectric layer WBO may include silicon oxide, and the blocking layer WBR may include silicon carbon oxide (SiCO), silicon carbon nitride, or a combination thereof. The lower structure LS may be a combination of the blocking layer WBR and the SOI structure. The SOI structure may refer to a stack of the substrate W10 and the bonding dielectric layer WBO. The SOI structure may be different from a SOI substrate. A typical SOI substrate may be a structure in which oxide is formed on a silicon substrate, but the SOI structure according to the present embodiment may be a structure in which the bonding dielectric layer WBO is formed on the substrate W10. The blocking layer WBR may be formed by alternately stacking first blocking layers BR1 with second blocking layers BR2. The first blocking layers BR1 may be silicon carbon oxide, and the second blocking layers BR2 may be silicon carbon nitride. In some embodiments, the first blocking layers BR1 may be silicon carbon nitride, and the second blocking layers BR2 may be silicon carbon oxide. Because the blocking layer WBR having a multilayer structure is formed, substrate bunkering may be further prevented.

According to various embodiments of the present disclosure, a SOI structure including a blocking layer is used when a 3D memory cell array is formed, which makes it possible to prevent substrate bunkering.

According to various embodiments of the present disclosure, the reliability of 3D memory cells may be improved.

While the embodiments of the present disclosure has been illustrated and described with respect to specific embodiments and drawings, the disclosed embodiments are not intended to be restrictive. Further, it is noted that the embodiments may be achieved in various ways through substitution, change, and modification, as those skilled in the art will recognize in light of the present disclosure, without departing from the spirit and/or scope of the present disclosure and the following claims. Furthermore, the embodiments may be combined to form additional embodiments.

What is claimed is:

1. A method for fabricating a semiconductor device, the method comprising:
forming a first bonding dielectric layer on a substrate;
sequentially forming a mold stack, a blocking layer, and a second bonding dielectric layer on a sacrificial substrate to create a stack structure;
flipping the stack structure including the sacrificial substrate;
bonding the first bonding dielectric layer and the second bonding dielectric layer;
removing the sacrificial substrate from the stack structure; and
forming a plurality of memory cells vertically stacked on the mold stack of the stack structure, using the blocking layer as a barrier.

2. The method of claim 1, wherein a lowermost memory cell of the memory cells vertically stacked is in direct contact with the blocking layer.

3. The method of claim 1, wherein the blocking layer includes silicon carbon oxide.

4. The method of claim 1, wherein the substrate and the sacrificial substrate each include monocrystalline silicon.

5. The method of claim 1, wherein the mold stack is formed by alternately stacking first semiconductor layers with second semiconductor layers.

6. The method of claim 5, wherein the first semiconductor layers each include silicon germanium, and the second semiconductor layers each include monocrystalline silicon.

7. The method of claim 5, wherein the first semiconductor layers and the second semiconductor layers are formed by epitaxial growth.

8. The method of claim 1, wherein forming the plurality of memory cells vertically stacked includes:
forming nano sheets;
forming a horizontal conductive line that surrounds the nano sheets;
forming a vertical conductive line coupled to one side of the nano sheets; and
forming data storage elements coupled to the nano sheets, each data storage element coupled to a different one of the other sides of the nano sheets.

9. A method for fabricating a semiconductor device, the method comprising:
forming a first bonding dielectric layer on a first substrate;
sequentially forming a mold stack, a blocking layer, and a second bonding dielectric layer on a sacrificial substrate to create a first structure;
flipping the first structure including the sacrificial substrate;
bonding the first bonding dielectric layer and the second bonding dielectric layer;
removing the sacrificial substrate from the stack structure;
forming a memory cell array including a plurality of memory cells vertically stacked in the mold stack, using the blocking layer as a barrier, to create a second structure;
forming a peripheral circuit portion over a second substrate;
flipping the second structure;
bonding the memory cell array and the peripheral circuit portion; and
removing the first substrate and the second bonding dielectric layer.

10. The method of claim 9, wherein the blocking layer includes silicon carbon oxide, silicon carbon nitride, or a combination thereof.

11. The method of claim 9, wherein the substrate and the sacrificial substrate each include monocrystalline silicon.

12. The method of claim 9, wherein the mold stack is formed by alternately stacking first semiconductor layers with second semiconductor layers.

13. The method of claim 12, wherein the first semiconductor layers each include silicon germanium, and the second semiconductor layers each include monocrystalline silicon.

14. The method of claim 12, wherein the first semiconductor layers and the second semiconductor layers are formed by epitaxial growth.

15. The method of claim 9, wherein forming the plurality of memory cells vertically stacked includes:
forming nano sheets;
forming a horizontal conductive line that surrounds the nano sheets;
forming a vertical conductive line coupled to one side of the nano sheets; and
forming data storage element coupled to the nano sheets, each data storage element coupled to a different one of the other sides of the nano sheets.

16. A semiconductor device comprising:
a substrate;
a bonding dielectric layer formed on the substrate;
a blocking layer formed on the bonding dielectric layer; and
a memory cell array formed over the blocking layer, the memory cell array including a plurality of memory cells vertically stacked over the blocking layer.

17. The semiconductor device of claim 16, wherein the blocking layer includes silicon carbon oxide, silicon carbon nitride, or a combination thereof.

18. The semiconductor device of claim 16, wherein the bonding dielectric layer includes a double bonding dielectric layer.

19. The semiconductor device of claim 16, wherein the bonding dielectric layer includes an oxide-to-oxide bonding structure.

20. The semiconductor device of claim 16, wherein each memory cell of the memory cell array includes:
a vertical conductive line;
a nano sheet horizontally extending from the vertical conductive line;
a horizontal conductive line surrounding the nano sheet; and
a data storage element coupled to the nano sheet.
